(19) United States
(12) Patent Application Publication
(10) Pub. No.: US 2026/0271513 A1
(43) Pub. Date: Sep. 10, 2026

(54) LIGHT-EMITTING ELEMENT, DISPLAY DEVICE, AND MANUFACTURING METHOD FOR LIGHT-EMITTING ELEMENT

(71) Applicant: Sharp Display Technology Corporation, Kameyama City, Mie (JP)

(72) Inventors: Takahiro ADACHI, Sakai City, Osaka (JP); YASUSHI ASAOKA, Sakai City, Osaka (JP); Sentaro KIDA, Sakai City, Osaka (JP)

(21) Appl. No.: 19/121,266

(22) PCT Filed: Oct. 19, 2022
(86) PCT No.: PCT/JP2022/038894

§ 371 Date: Apr. 15, 2025

(51) Int. Cl. H10K 50/844; H10K 50/115

(52) U.S. Cl. CPC H10K 50/844; H10K 50/115

(57) ABSTRACT

To prevent a light-emitting layer from being deteriorated by moisture transmitting a sealing agent and infiltrating into the light-emitting layer in a trace amount. A light-emitting element includes, on a substrate, a charge transport layer and a charge transport layer layered between an electrode and an electrode, a light-emitting layer layered between the charge transport layer and the charge transport layer, and a water-soluble resin layer in contact with the light-emitting layer, in which the water-soluble resin layer includes a water-soluble resin.

### TECHNICAL FIELD

The disclosure relates to a light-emitting element, a display device, and a method for manufacturing a light-emitting element.

### BACKGROUND ART

In recent years, various display devices provided with light-emitting elements have been developed. In particular, a display device provided with a quantum dot light-emitting diode (QLED) or an organic light-emitting diode (OLED) has attracted a great deal of attention from perspectives such as the capability to achieve lower power consumption, a slimmer design, and higher picture quality.

For example, PTL 1 describes an organic electroluminescent element in which an organic function layer is interposed between a pair of electrodes, the organic function layer includes a liquid phase forming layer formed by a liquid phase method, and the liquid phase forming layer is formed on an intermediate layer having a surface modifying function.

### CITATION LIST

### Patent Literature

PTL 1: JP 2005-235569 A

### SUMMARY

### Technical Problem

However, even when the light-emitting element is subjected to sealing treatment in the above-described technique in the related art, there is a problem in that deterioration of the light-emitting layer proceeds due to moisture (also referred to as a dampness content) infiltrating from the outside of the light-emitting element.

That is, the disclosure has been made in view of the above-described problem, and an object thereof is to provide a novel light-emitting element capable of reducing the possibility of deterioration of the light-emitting layer due to infiltration of moisture, and a technique related thereto.

### Solution to Problem

A light-emitting element according to an aspect of the disclosure includes: first and second electrodes; a plurality of charge transport layers layered between the first and second electrodes; a light-emitting layer layered between the plurality of charge transport layers; and at least one water-soluble resin layer in contact with at least one surface selected from a front surface, a back surface, and an outer peripheral end surface of the light-emitting layer, in which the water-soluble resin layer includes a water-soluble resin.

A display device according to an aspect of the disclosure is a display device including: a substrate; and a plurality of light-emitting elements on the substrate, in which each of the plurality of light-emitting elements includes first and second electrodes, a plurality of charge transport layers layered between the first and second electrodes, a light-emitting layer layered between the plurality of charge transport layers, and at least one water-soluble resin layer in contact with at least one surface selected from a front surface, a back surface, and an outer peripheral end surface of the light-emitting layer, and the water-soluble resin layer includes a water-soluble resin.

A method for manufacturing a light-emitting element according to an aspect of the disclosure is a method for manufacturing a light-emitting element, the light-emitting element including a light-emitting layer, and at least one water-soluble resin layer in contact with the light-emitting layer, a composition for forming the water-soluble resin layer including a water-soluble resin and a positive-working photosensitizer, the method including: water-soluble resin layer formation of applying the composition onto a substrate; pattern developing of exposing a portion of the applied composition to light to develop a pattern on the water-soluble resin layer; light-emitting layer formation of forming the light-emitting layer in contact with the pattern; and light-emitting layer peeling and developing of peeling at least a portion of the water-soluble resin layer other than the pattern to peel and develop the light-emitting layer on the pattern.

### Advantageous Effects of Disclosure

According to the disclosure, it is possible to provide a novel light-emitting element capable of reducing the possibility of deterioration of the light-emitting layer due to infiltration of moisture, and a technique related thereto.

### BRIEF DESCRIPTION OF DRAWINGS

FIG. 1 is a cross-sectional view illustrating a schematic configuration of a light-emitting element 100 according to an embodiment of the disclosure.

FIG. 2 is a cross-sectional view illustrating a schematic configuration of a light-emitting element 101 according to a modified example of the disclosure.

FIG. 3 is a cross-sectional view illustrating a schematic configuration of a light-emitting element 102 according to a modified example of the disclosure.

FIG. 4 is a cross-sectional view illustrating a schematic configuration of a light-emitting element 103 according to a modified example of the disclosure.

FIG. 5 is a cross-sectional view illustrating a schematic configuration of a light-emitting element 104 according to a modified example of the disclosure.

FIG. 6 is a cross-sectional view illustrating a schematic configuration of a light-emitting element 105 according to a modified example of the disclosure.

FIG. 7 is a plan view illustrating a schematic configuration of a display device 200 according to an embodiment of the disclosure.

FIG. 8 is a cross-sectional view illustrating a schematic configuration of the display device 200 according to the embodiment of the disclosure.

FIG. 9 is a cross-sectional view illustrating a schematic configuration of a display device 210 according to a modified example of the disclosure.

FIG. 10 is a cross-sectional view illustrating a schematic configuration of a display device 220 according to a modified example of the disclosure.

FIG. 11 is a cross-sectional view schematically illustrating steps from a step of forming a water-soluble resin layer 43A to a step of exposing the water-soluble resin layer 43A to light included in a developing step, included in a method for manufacturing a light-emitting element according to an embodiment of the disclosure.

FIG. 12 is a cross-sectional view schematically illustrating a step of developing a pattern on the exposed water-soluble resin layer 43A, included in the method for manufacturing a light-emitting element according to the embodiment of the disclosure.

FIG. 13 is a cross-sectional view schematically illustrating a step of forming a first light-emitting layer 53B, included in the method for manufacturing a light-emitting element according to the embodiment of the disclosure.

FIG. 14 is a cross-sectional view schematically illustrating a step of peeling and developing the first light-emitting layer 53B, included in the method for manufacturing a light-emitting element according to the embodiment of the disclosure.

FIG. 15 is a cross-sectional view schematically illustrating adjustment of a thickness t1 of the water-soluble resin layer 43A in the peeling and developing step in the method for manufacturing a light-emitting element according to the embodiment of the disclosure.

FIG. 16 is a cross-sectional view schematically illustrating a step of forming a water-soluble resin layer 43B (second step of forming a water-soluble resin layer) included in the method for manufacturing a light-emitting element according to an embodiment of the disclosure.

FIG. 17 is a cross-sectional view schematically illustrating steps until exposing the water-soluble resin layer 43B to light (second time), included in the method for manufacturing a light-emitting element according to the embodiment of the disclosure.

FIG. 18 is a cross-sectional view schematically illustrating a step of developing a pattern on the water-soluble resin layer 43B (second developing step), included in the method for manufacturing a light-emitting element according to the embodiment of the disclosure.

FIG. 19 is a cross-sectional view schematically illustrating a step of forming a second light-emitting layer 53R (second step of forming a light-emitting layer), included in the method for manufacturing a light-emitting element according to the embodiment of the disclosure.

FIG. 20 is a cross-sectional view schematically illustrating a step of peeling and developing the second light-emitting layer 53R (second peeling and developing step), included in the method for manufacturing a light-emitting element according to the embodiment of the disclosure.

FIG. 21 is a cross-sectional view schematically illustrating steps from a step of forming a water-soluble resin layer 43C (third step of forming a water-soluble resin layer) to a step of exposing the water-soluble resin layer 43C to light, included in the method for manufacturing a light-emitting element according to the embodiment of the disclosure.

FIG. 22 is a cross-sectional view schematically illustrating a step (third developing step) of developing a pattern on the water-soluble resin layer 43C included in the method for manufacturing a light-emitting element according to the embodiment of the disclosure.

FIG. 23 is a cross-sectional view schematically illustrating a step of forming a third light-emitting layer 53G (third step of forming a light-emitting layer) included in the method for manufacturing a light-emitting element according to the embodiment of the disclosure.

FIG. 24 is a cross-sectional view schematically illustrating a step (third peeling and developing step) of peeling and developing the third light-emitting layer 53G included in the method for manufacturing a light-emitting element according to the embodiment of the disclosure.

FIG. 25 is a cross-sectional view schematically illustrating a display device 230 manufactured by the method for manufacturing a light-emitting element according to the embodiment of the disclosure.

### DESCRIPTION OF EMBODIMENTS

### Light-Emitting Element

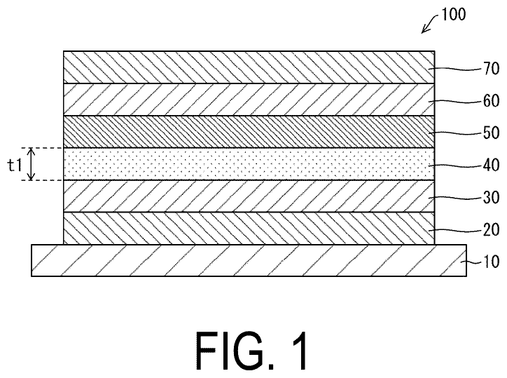

First, a configuration of a light-emitting element 100 including a quantum dot light-emitting diode (QLED) according to an embodiment of the disclosure will be described based on FIG. 1. FIG. 1 is a cross-sectional view illustrating a schematic configuration of the light-emitting element 100 according to the present embodiment.

In the present specification, for each layer in each cross-sectional view, a surface located on the upper side is referred to as a front surface (first surface), a surface located on the lower side is referred to as a back surface (second surface), and surfaces located at both ends are referred to as outer peripheral end surfaces (third surfaces).

As illustrated in FIG. 1, in the light-emitting element 100 according to the present embodiment, a first charge transport layer 30, which is a hole transport layer, a water-soluble resin layer 40, a light-emitting layer 50, and a second charge transport layer 60, which is an electron transport layer, are layered in this order between a first electrode 20, which is an anode provided on a substrate 10, and a second electrode 70, which is a cathode, and the water-soluble resin layer 40 is provided to be in contact with the back surface of the light-emitting layer 50. A layer layered between the first and second electrodes may be referred to as a function layer, and the function layer is a layer including a plurality of charge transport layers, a light-emitting layer layered between the plurality of charge transport layers, and a water-soluble resin layer in contact with the light-emitting layer.

The light-emitting element 100 constitutes a light-emitting region of a display region included in a display device on the substrate 10, and is surrounded by a non-light-emitting region which does not emit light on the substrate 10.

The light-emitting element 100 illustrated in FIG. 1 may be of a top-emitting type or a bottom-emitting type. In the light-emitting element 100, the second electrode 70, which is a cathode, only need be provided in an upper layer above the first electrode 20, which is an anode. The first electrode 20, which is an anode, only need be formed using an electrode material that reflects visible light, and the second electrode 70, which is a cathode, only need be formed using an electrode material that transmits visible light. To obtain a bottom-emitting type, in the light-emitting element 100, the second electrode 70, which is a cathode, only need be provided in an upper layer above the first electrode 20, which is an anode. The first electrode 20, which is an anode, only need be formed using an electrode material that transmits visible light, and the second electrode 70, which is a cathode, only need be formed using an electrode material that reflects visible light.

The electrode material that reflects visible light is not particularly limited as long as the material can reflect visible light and has electrical conductivity, and examples thereof include metal materials such as Al, Cu, Au, Mg, Li, and Ag, alloys of the metal materials, layered bodies of the metal materials and transparent metal oxides (for example, indium tin oxide, indium zinc oxide, indium gallium zinc oxide, and the like), or layered bodies of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

In one embodiment, the light-emitting element may have a normal layered structure as illustrated in FIG. 1, but is not limited thereto and may have a reverse layered structure. Although not illustrated, a light-emitting element having a reverse layered structure can be formed by layering the first charge transport layer which is an electron transport layer, the water-soluble resin layer, the light-emitting layer, the second charge transport layer which is a hole transport layer, and the second electrode which is an anode in this order from the first electrode which is a cathode.

### First Charge Transport Layer

The light-emitting element 100 includes the first charge transport layer 30 between the first electrode 20 and the light-emitting layer 50. The first charge transport layer 30, which is a hole transport layer, transports positive holes from the first electrode 20, which is an anode, through the water-soluble resin layer 40 toward the light-emitting layer 50.

Although not illustrated, the first charge transport layer 30 may be composed of a plurality of layers from the viewpoint of enhancing the hole injection efficiency. In a case where the first charge transport layer 30 includes a plurality of hole transport layers, one of the hole transport layers may be referred to as a hole injection layer. In a case where the first charge transport layer includes a hole injection layer, in the first charge transport layer, the hole injection layer may be formed on the first electrode which is an anode, and the hole transport layer may be formed on the hole injection layer.

### Hole Injection Layer

The first charge transport layer 30 may be a hole injection layer that injects positive holes. The hole injection layer is also a layer that transports positive holes from the first electrode 20 side through the water-soluble resin layer 40 toward the light-emitting layer 50, and thus may be an aspect of the hole transport layer. Examples of a hole injection material included in the hole injection layer include a nanoparticle of NiO, CuI, Cu₂O, CoO, Cr₂O₃, or CuAlS₂. The nanoparticle which is a hole injection material may include thiol, amine, or the like as a ligand.

### Hole Transport Layer

The first charge transport layer 30 may be a hole transport layer that transports positive holes. The hole transport layer is a layer that transports positive holes from the first electrode 20 side, which is an anode, toward the light-emitting layer 50. The hole transport layer may be formed on the first electrode 20, which is an anode, or on the hole injection layer.

A material to be used for the hole transport layer is not particularly limited as long as the material is a hole transport material capable of stabilizing the transport of positive holes into the light-emitting layer 50. The hole transport material in the hole transport layer preferably has high hole mobility. Furthermore, the hole transport material is preferably a material (electron blocking material) capable of preventing penetration of electrons that have traveled from the second electrode 70 which is a cathode. This makes it possible to increase a recombination efficiency of positive holes and electrons within the light-emitting layer 50. The hole transport material is preferably, for example, a photosensitive hole transport material having a cation polymerizable functional group such as an oxetane ring, and examples of the photosensitive hole transport material include N,N′-(4,4′-(cyclohexane-1,1-diyl)bis(4,1-phenylene))bis(N-(4-(6-(2-ethyloxetan-2-yloxy)hexyl)phenyl)-3,4,5-trifluoroaniline), N4,N4′-bis(4-(6-((3-ethyloxetan-3-yl)methoxy)hexyloxyphenyl)-N4,N4′-bis(4-methoxyphenyl)biphenyl-4,4′-diamine, and N4,N4′-bis(4-(6-((3-ethyloxetan-3-yl)methoxy)hexyl)phenyl)-N4,N4′-diphenylbiphenyl-4,4′-diamine. The photosensitive hole transport material included in the hole transport layer may be cationically polymerized by, for example, a photoacid generator or the like. In addition, the hole transport layer may include a product generated by exposure of the photoacid generator to light. Besides, examples of the hole transport material include poly-TPD, polyvinyl carbazole (PVK), and poly[(9,9-dioctylfluorenyl-2,7-diyl)-co-(4,4′-(N-(4-sec-butylphenyl))diphenylamine)] (TFB).

### Water-Soluble Resin Layer

The water-soluble resin layer 40 is a layer that protects the light-emitting layer 50 from moisture infiltrating into the light-emitting element 100 from the outside of the display device. In the light-emitting element 100 according to one embodiment, the water-soluble resin layer 40 is in close contact with the front surface of the first charge transport layer 30 and is in close contact with the back surface of the light-emitting layer 50, whereby moisture can be prevented from infiltrating into the light-emitting layer 50 from the first charge transport layer 30 side. The back surface of the water-soluble resin layer 40 is in contact with the entire front surface of the first charge transport layer 30 which is a hole transport layer. Thus, in the light-emitting element 100, the light-emitting layer 50 and the first charge transport layer 30 are not in direct contact with each other.

As will be described below, the water-soluble resin layer 40 is a layer formed using a composition containing a water-soluble resin and a positive-working photosensitizer.

The water-soluble resin is a thermoplastic resin having water solubility, and is a water-soluble resin that dissolves in pure water and an alkaline aqueous solution. From the viewpoint of preventing re-release of the collected moisture, a water-soluble resin having higher hydrophilicity than that of an amphiphilic molecule is preferable. The water-soluble resin contains monomer units derived from hydrophilic monomers different from each other, and the water solubility thereof can be determined to be a solubility parameter (SP value) of the water-soluble resin. The SP value of the water-soluble resin only need be roughly estimated with reference to the SP value of a monomer constituting a monomer unit contained in the water-soluble resin or the SP value of a homopolymer.

Here, the SP value of the water-soluble resin can be divided into three terms as shown in the following equation (1).

$$δ ( solubility parameter ) = {( {δ}_{D}^{2} + {δ}_{P}^{2} + {δ}_{H}^{2} )}^{1 / 2} \qquad ( 1 )$$

(In the equation (1), δ_{D} is a dispersion term, δ_{P} is a polar term, and δ_{H} is a hydrogen bonding term.)

Among the parameters shown in the equation (1), the water-soluble resin preferably has a polar term δ_{P} of 5.0 or more from the viewpoint of increasing the solubility of the water-soluble resin layer in an organic solvent developer and increasing the resistance to dissolution in an alkaline developer. The polar term δ_{P} only need be obtained from, for example, Hansen solubility parameter estimation software, and only need be roughly estimated from the polar term δ_{P} of the monomer constituting the water-soluble resin and the molar ratio of the monomer unit contained in the water-soluble resin.

The water-soluble resin has good compatibility with the hole injection material and the hole transport material that have been described above and a light-emitting material to be described below. Thus, adhesion between the first charge transport layer 30 and the water-soluble resin layer 40 can be enhanced, and adhesion between the water-soluble resin layer 40 and the light-emitting layer 50 can be enhanced. Accordingly, it is possible to suitably prevent infiltration of moisture from the outside between the first charge transport layer 30 and the light-emitting layer 50.

The water-soluble resin is preferably a block copolymer or a graft copolymer containing two or more types of polymer units derived from hydrophilic monomers different from each other, and more preferably a graft copolymer. Here, each of the polymer units may be a homopolymer or a copolymer of a monomer unit derived from a monomer having water solubility. In a case where the water-soluble resin is a block copolymer or a graft copolymer containing two or more types of polymer units, the film-forming properties of the water-soluble resin can be suitably controlled by difference in water solubility between the polymer units.

The type of the monomer unit constituting the polymer unit contained in the water-soluble resin only need be selected depending on the water solubility of a homopolymer of each monomer unit. The water solubility of a homopolymer of each monomer unit only need be roughly estimated with reference to the SP value of the homopolymer or the SP value of the monomer. In a case where the water-soluble resin is a block copolymer or a graft copolymer, a polymer unit having relatively low water solubility may be referred to as a first polymer unit, and a polymer unit having relatively high water solubility may be referred to as a second polymer unit. The difference (difference in SP value) between the water solubility of the first polymer unit and the water solubility of the second polymer unit is preferably large.

As the monomer unit constituting the first polymer unit, for example, a monomer having an SP value in a range of 9.0 to 15.0 can be exemplified, and examples thereof include (meth)acrylic acid (SP value: 9.6), (meth)acrylamide (SP value: 9.0 to 15.0), N-vinylacetamide (SP value: 10.9), polyvinyl alcohol (SP value: 12.6), ethylene glycol (SP value: 14.2), and ethylenediamine (SP value: 12.4). Note that the SP value of polyvinyl alcohol can be determined to be the SP value of a homopolymer of vinyl alcohol. In a case where the monomer is (meth)acrylic acid, the (meth)acrylic acid may be contained in the first polymer unit as an alkali metal salt or an ammonium salt. Examples of the monomer unit derived from these monomers and the like include a vinyl alcohol monomer unit, a monomer unit derived from (meth)acrylic acid, a monomer unit derived from (meth)acrylic acid salt, a monomer unit derived from (meth)acrylamide, and a monomer unit derived from N-vinylacetamide, and a vinyl alcohol monomer unit is preferable. Other examples of the monomer unit include an ethylene oxide unit, an ethylene amine unit, and a propylene amine unit. The water-soluble monomer unit constituting the first polymer unit may be, for example, a monomer unit derived from a monomer having a hydrophilic group such as a carboxyl group, a hydroxyl group, an amino group, or an amide group, or may be a monomer unit forming a hydrophilic main chain exemplified by a polyether chain such as polyethylene glycol, a polyamine chain such as spermine or spermidine, or the like by polymerization.

The monomer constituting the second polymer unit preferably has an SP value of more than 15.0, and more preferably 20.0 or more. Examples of the monomer constituting the second polymer unit include vinylpyrrolidone (SP value: 26.2).

In the present specification, “(meth)acrylic acid” includes the meaning of both “acrylic acid” and “methacrylic acid”, and “(meth)acrylamide” includes the meaning of both “acrylamide” and “methacrylamide”.

Examples of the first polymer unit included in the block copolymer or the graft copolymer include a homopolymer unit of a monomer unit derived from vinyl alcohol (that is, a vinyl alcohol monomer unit), and examples of the second polymer unit include a homopolymer unit of a monomer unit derived from N-vinylpyrrolidone (that is, an N-vinylpyrrolidone monomer unit).

In the polymer unit obtained by polymerization of the vinyl alcohol monomer unit, that is, the vinyl alcohol polymer unit, water solubility may be adjusted by substituting a part of hydrogen in a hydroxyl group thereof with a hydrophobic group. Here, examples of the hydrophobic group include an epoxy group and a (meth)acryloyl group.

The water-soluble resin may be designed by a ratio of the first polymer unit and the second polymer unit contained in the block copolymer or the graft copolymer. More specifically, for example, the total molar amount of the monomer units contained in the first polymer unit and the second polymer unit is assumed to be 1.0, and a proportion occupied by the molar amount of the monomer unit contained in the first polymer unit is adjusted, whereby it is possible to control film forming properties in the water-soluble resin. Furthermore, for example, the larger the molar ratio of the monomer unit contained in the first polymer unit, the more the first polymer unit can be oriented to the front surface of the water-soluble resin layer 40, that is, the surface facing the back surface of the light-emitting layer 50. As a result, the interface between the front surface of the water-soluble resin layer 40 and the back surface of the light-emitting layer 50 can be made uniform, the concentration of charges on the interface can be suppressed, and the reliability of the light-emitting element can be improved.

For example, in a case where a vinyl alcohol polymer unit is adopted as the first polymer unit, the ratio of the first polymer unit contained in the water-soluble resin is described as a polyvinyl alcohol (PVA) ratio.

For example, in a case where the block copolymer or the graft copolymer contains a homopolymer unit of a monomer unit derived from vinyl alcohol as the first polymer unit and a homopolymer unit of a monomer unit derived from N-vinylpyrrolidone as the second polymer unit, the PVA ratio, which is the ratio of the first polymer unit, is preferably from 0.3 to 0.9. When the PVA ratio is greater than 0.3, for example, it is possible to prevent the water-soluble resin from being excessively removed when the water-soluble resin layer is formed, by an alkali aqueous solution or the like. When the PVA ratio is smaller than 0.9, it is possible to prevent the water-soluble resin from excessively remaining. The ratio between the first polymer unit and the second polymer unit in the block copolymer or the graft copolymer may be adjusted in line with the value of the PVA ratio of 0.3 to 0.9.

The water-soluble resin is preferably a block copolymer or a graft copolymer, but is not limited thereto, and may be a homopolymer of a monomer unit derived from a monomer having water solubility, or a copolymer containing monomer units derived from two or more types of monomers having water solubility.

The positive-working photosensitizer contained in the water-soluble resin layer 40 is typically a diazoquinone compound. In the water-soluble resin layer 40, the positive-working photosensitizer may be contained as the diazoquinone compound itself or a product generated from the diazoquinone compound by exposure to light.

In the light-emitting element 100, a thickness t1 of the water-soluble resin layer 40 located between the front surface of the first charge transport layer 30 and the back surface of the light-emitting layer 50 is preferably 20 μm or less. When the thickness t1 of the water-soluble resin layer 40 is 20 μm or less, positive holes transported from the first charge transport layer 30, which is a hole transport layer, can be suitably moved to the light-emitting layer 50. This can improve carrier balance between the first charge transport layer 30 and the second charge transport layer 60 in the light-emitting element 100. When the thickness t1 of the water-soluble resin layer 40 is 5 nm or more, it is possible to prevent moisture from infiltrating into the light-emitting layer 50 from the first charge transport layer 30 side, which is a hole transport layer.

### Light-Emitting Layer

The light-emitting layer 50 emits light due to the recombination of positive holes transported from the first electrode 20, which is an anode, and electrons transported from the second electrode 70, which is a cathode. In the present embodiment, the light-emitting layer 50 is a quantum dot light-emitting layer including any of quantum dots (QDs: semiconductor nanoparticles) of respective colors as a light-emitting material, but is not limited thereto and may be an organic light-emitting diode (OLED).

The light-emitting layer 50 can emit any of red light, green light, and blue light. Here, the red light is light having a light emission central wavelength in a wavelength band longer than 600 nm and shorter than or equal to 780 nm. Further, the green light is light having a light emission central wavelength in a wavelength band longer than 500 nm and shorter than or equal to 600 nm. Furthermore, the blue light is light having a light emission central wavelength in a wavelength band from 400 nm to 500 nm. Note that, in one embodiment, the quantum dots of the plurality of types are combinations of the red quantum dots, the green quantum dots, and the blue quantum dots, but the quantum dots need not necessarily be one of those combinations.

The light-emitting layer 50 may include, for example, a continuous film of a metal sulfide and a plurality of quantum dots included in the continuous film. The metal sulfide may be, for example, a sulfide semiconductor of ZnS (zinc sulfide), ZnTeS, ZnMgS₂, MgS, Ga₂S₃, ZnGa₂S₄, or MgGa₂S₄. The continuous film may have an area of 1000 nm² or more in a plane direction orthogonal to the thickness direction at any position in the thickness direction of the light-emitting layer 50, for example. The average thickness of the light-emitting layer 50 may be 10 nm or more and 100 nm or less, and the maximum value of the thickness of the light-emitting layer 50 may be equal to or less than twice the minimum value thereof.

Each of the quantum dots (QDs) included in the light-emitting layer 50 may have, for example, a core structure, a core/shell structure, a core/shell/shell structure, or a core/shell with continuously varying ratio structure. In a case where the quantum dot (QD) has a core structure, ligands are provided on the surface of the core, and in a case where the quantum dot (QD) has a structure having a shell, the ligands are provided on the surface of the shell. The core portion of the quantum dot (QD) may be composed of, for example, Si, C, or the like in a case of a unitary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AIGS or the like in a case of a quaternary system. The shell portion can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AIP, or the like in a case of a ternary system.

Note that the quantum dot (QD) is a dot having a maximum width of 100 nm or less. A shape of the quantum dot (QD) is not limited to a specific shape as long as it is within a range satisfying the maximum width, and is not limited to a spherical three-dimensional shape (circular cross-sectional shape). The shape may be, for example, a polygonal cross-sectional shape, a rod-shaped three-dimensional shape, a branch-shaped three-dimensional shape, or a three-dimensional shape having unevenness on the surface thereof, or a combination of them.

The ligand included in the quantum dot (QD) may be an inorganic ligand or an organic ligand. In a case where the ligand included in the quantum dot (QD) is an organic ligand, the organic ligand may be an organic compound including a functional group such as amine or thiol. The quantum dot (QD) may include the inorganic ligand described above and may further include an organic ligand. In a case where the ligand included in the quantum dot (QD) is an inorganic ligand, the ligand may be, for example, a halogen ligand including a halogen atom. In this case, the average value of the concentration of halogen atoms within the distance of 1 nm from the outermost surface of each of the quantum dots (QDs) may be 10%, 50%, or 100% higher than the average value of the concentration of halogen atoms at other positions.

### Second Charge Transport Layer

The light-emitting element 100 includes the second charge transport layer 60 between the second electrode 70 and the light-emitting layer 50. In a case where the second electrode 70 is a cathode, the second charge transport layer 60 is an electron transport layer. The second charge transport layer 60, which is an electron transport layer, transports electrons from the second electrode 70, which is a cathode, toward the light-emitting layer 50. Note that although not illustrated, the second charge transport layer may be composed of a plurality of layers.

The material used for the electron transport layer is not particularly limited as long as the material is an electron transporting material capable of stabilizing the transport of the electrons to the light-emitting layer 50. Examples of the electron transporting material include nanoparticles of ZnO, ZnS, ZrO, MgZnO, AlZnO, TiO₂, or the like, and these nanoparticles may include ligands such as organic ligands and inorganic ligands on their surfaces.

### Light-Emitting Element 101 According to One Modified Example

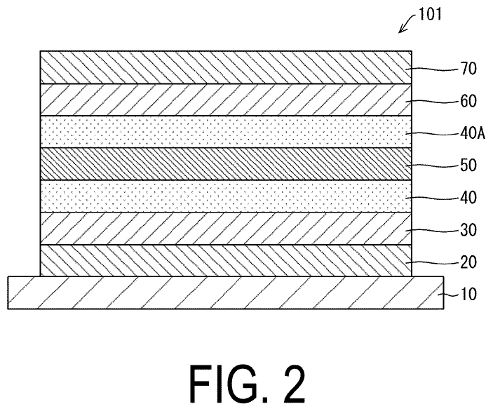

The light-emitting element according to one embodiment of the disclosure is not limited to the embodiment described above. FIG. 2 is a cross-sectional view illustrating a schematic configuration of a light-emitting element 101 according to one modified example of the disclosure. The same members as those of the light-emitting element 100 are denoted by the same reference numerals, and description thereof will be omitted.

The light-emitting element 101 includes a water-soluble resin layer of a first layer (first water-soluble resin layer) 40 in contact with the back surface of the light-emitting layer 50 and a water-soluble resin layer of a second layer (second water-soluble resin layer) 40A in contact with the front surface of the light-emitting layer 50. In the light-emitting element 101, the water-soluble resin layer 40 and the water-soluble resin layer 40A are in close contact with the front and back surfaces of the light-emitting layer 50, thereby preventing moisture from infiltrating into the light-emitting layer 50.

The first water-soluble resin layer refers to a water-soluble resin layer in contact with the back surface of the light-emitting layer, and the second water-soluble resin layer refers to a water-soluble resin layer in contact with the front surface of the light-emitting layer. Further, one or both of the first and second water-soluble resin layers may be in contact with the outer peripheral end surface of the light-emitting layer. The water-soluble resin layer in contact with only the outer peripheral end surface of the light-emitting layer refers to a third water-soluble resin layer, and is distinguished from the first and second water-soluble resin layers.

In a case where one continuous water-soluble resin layer is formed in a plurality of light-emitting elements, the water-soluble resin layer may be formed as a first water-soluble resin layer in contact with the back surface of the light-emitting layer included in one light-emitting element (first light-emitting element) and may be formed as a second water-soluble resin layer in contact with the front surface of the light-emitting layer included in another light-emitting element (second light-emitting element).

The water-soluble resin contained in the water-soluble resin layer 40A may have the same composition as that of the water-soluble resin contained in the above-described water-soluble resin layer 40, or may have a different composition from that of the water-soluble resin contained in the water-soluble resin layer 40. The water-soluble resin layer 40A is a layer containing at least a water-soluble resin, and may contain a positive-working photosensitizer. The water-soluble resin layer 40A may be a layer formed of a water-soluble resin composition containing a water-soluble resin and a positive-working photosensitizer.

The water-soluble resin contained in the water-soluble resin layer 40A only need be selected depending on the material of the light-emitting layer 50 in contact with the back surface thereof. The mass average molecular weight of the water-soluble resin contained in the water-soluble resin layer 40A is preferably larger than the mass average molecular weight of the water-soluble resin contained in the water-soluble resin layer 40. When the mass average molecular weight of the water-soluble resin contained in the water-soluble resin layer 40A is larger than the mass average molecular weight of the water-soluble resin contained in the water-soluble resin layer 40, it is possible to protect the light-emitting layer 50.

The water-soluble resin layer 40A has a thickness between the front surface of the light-emitting layer 50 and the back surface of the second charge transport layer 60, which is an electron transport layer, preferably in a range of 5 to 50 nm. Thus, in a case where carriers injected from the second charge transport layer 60 into the light-emitting layer 50 are excessive, the excessive carriers are blocked by the water-soluble resin layer 40A, the carrier balance in the light-emitting layer 50 is improved, and the luminous efficiency is improved.

### Light-Emitting Element 102 According to One Modified Example

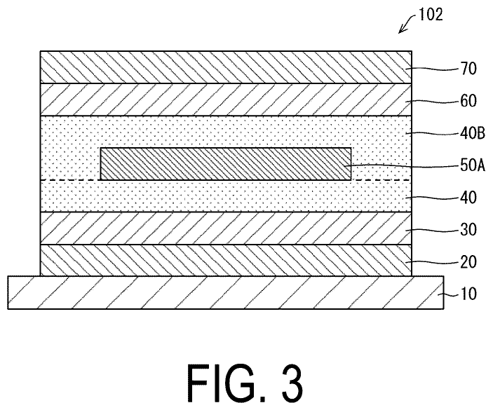

The light-emitting element according to one embodiment of the disclosure is not limited to the above-described embodiment and modified example. FIG. 3 is a cross-sectional view illustrating a schematic configuration of a light-emitting element 102 according to one modified example of the disclosure.

The light-emitting element 102 includes a water-soluble resin layer of a first layer (first water-soluble resin layer) 40 in contact with the back surface of a light-emitting layer 50A and a water-soluble resin layer of a second layer (second water-soluble resin layer) 40B in contact with the front surface of a light-emitting layer 50A. While the water-soluble resin layer 40B surrounds the outer peripheral end surface of the light-emitting layer 50A, the water-soluble resin layer 40B is in contact with the outer peripheral end surface. In the light-emitting element 102, all surfaces of the light-emitting layer 50A including the front surface, the back surface, and the outer peripheral end surface are covered with the water-soluble resin layer 40 and the water-soluble resin layer 40B, thereby preventing infiltration of moisture. In the light-emitting element 102, the back surface of the water-soluble resin layer 40 is in contact with the front surface of the first charge transport layer 30, which is a hole transport layer, whereby the light-emitting layer 50A is not in direct contact with the first charge transport layer 30.

The water-soluble resin contained in the water-soluble resin layer 40B only need be selected depending on the type of the light-emitting material contained in the light-emitting layer 50A as in the water-soluble resin layer 40A.

### Light-Emitting Element 103 According to One Modified Example

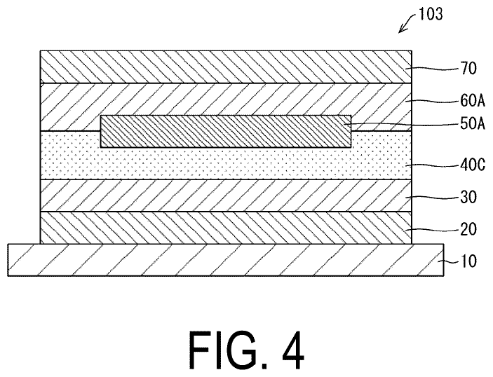

The light-emitting element according to one embodiment of the disclosure is not limited to the above-described embodiment and modified examples. FIG. 4 is a cross-sectional view illustrating a schematic configuration of a light-emitting element 103 according to one modified example of the disclosure.

In the light-emitting element 103, the back surface of the light-emitting layer 50A is in contact with the front surface of a water-soluble resin layer (first water-soluble resin layer) 40C, and the back surface of a second charge transport layer 60A is in contact with the front surface of the light-emitting layer 50A. The water-soluble resin layer 40C and the second charge transport layer 60A are in contact with the outer peripheral end surface of the light-emitting layer 50A while surrounding the outer peripheral end surface of the light-emitting layer 50A. In the light-emitting element 103, a region of the front surface of the water-soluble resin layer 40C, which is not in contact with the light-emitting layer 50A, and a region of the back surface of the second charge transport layer 60A, which is not in contact with the light-emitting layer 50A, are in close contact with each other. In the light-emitting element 103, the water-soluble resin layer 40C and the second charge transport layer 60A prevent moisture from infiltrating into the light-emitting layer 50A.

In the light-emitting element 103, the thickness of the water-soluble resin layer 40C between the front surface of the first charge transport layer 30 and the back surface of the light-emitting layer 50A may be designed in the same manner as in the thickness t1 of the water-soluble resin layer 40. In addition, the water-soluble resin layer 40C is thicker in the region not in contact with the light-emitting layer 50A than in the region in contact with the light-emitting layer 50A. In the light-emitting element 103, the water-soluble resin layer 40C prevents infiltration of moisture from the side surface of the light-emitting layer 50A.

The back surface of the water-soluble resin layer 40C included in the light-emitting element 103 is in contact with the entire front surface of the first charge transport layer 30 which is a hole transport layer. Thus, in the light-emitting element 103, the light-emitting layer 50A and the first charge transport layer 30 are not in direct contact with each other.

### Light-Emitting Element 104 According to One Modified Example

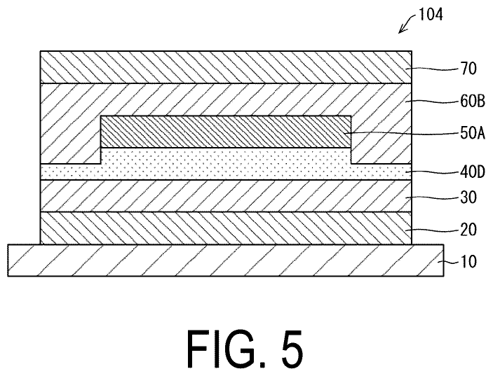

The light-emitting element according to one embodiment of the disclosure is not limited to the above-described embodiment and modified examples. FIG. 5 is a cross-sectional view illustrating a schematic configuration of a light-emitting element 104 according to one modified example of the disclosure.

In the light-emitting element 104 according to one modified example, a second charge transport layer 60B is in contact with the outer peripheral end surface while surrounding the outer peripheral end surface of the light-emitting layer 50A, and a partial region of the front surface of a water-soluble resin layer (first water-soluble resin layer) 40D is in contact with the back surface of the light-emitting layer 50A. The front surface of the water-soluble resin layer 40D includes a region in contact with the back surface of the light-emitting layer 50A and a region not in contact with the back surface of the light-emitting layer 50A, and the region not in contact with the back surface of the light-emitting layer 50A is in contact with the back surface of the second charge transport layer 60B which is an electron transport layer. In the light-emitting element 104, the water-soluble resin layer 40D is in close contact with the first charge transport layer 30, and the region not in contact with the back surface of the light-emitting layer 50A is in close contact with the back surface of the second charge transport layer 60B, thereby preventing infiltration of moisture through the interface between the first charge transport layer 30 and the second charge transport layer 60B.

The water-soluble resin layer 40D included in the light-emitting element 104 can have a thickness between the front surface of the first charge transport layer 30 and the back surface of the light-emitting layer 50A may be the same as the thickness t1 of the water-soluble resin layer 40 included in the light-emitting element 100. However, the water-soluble resin layer 40D may have a smaller thickness in a region not in contact with the light-emitting layer 50A, that is, between the front surface of the first charge transport layer 30 and the front surface of the second charge transport layer 60 than the thickness t1.

### Light-Emitting Element 105 According to One Modified Example

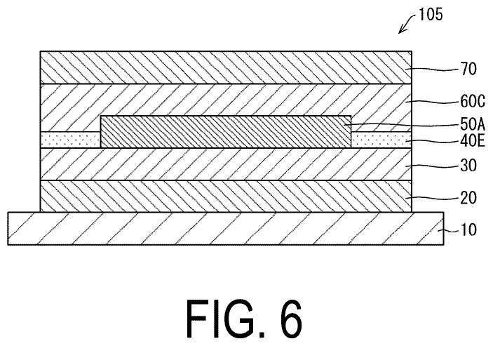

The light-emitting element according to one embodiment of the disclosure is not limited to the above-described embodiment and modified examples. FIG. 6 is a cross-sectional view illustrating a schematic configuration of a light-emitting element 105 according to one modified example of the disclosure.

As illustrated in FIG. 6, in the light-emitting element 105, a water-soluble resin layer (third water-soluble resin layer) 40E is in close contact with the outer peripheral end surface of the light-emitting layer 50A and is in close contact with the front surface of the first charge transport layer 30 and the back surface of a second charge transport layer 60C. Thus, in the light-emitting element 105, moisture is prevented from infiltrating into the light-emitting layer 50A from the interface between the front surface of the first charge transport layer 30 and the back surface of the second charge transport layer 60C.

In the light-emitting element 105, the front surface of the first charge transport layer 30 and the back surface of the light-emitting layer 50A are in contact with each other, and the front surface of the light-emitting layer 50A and the back surface of the second charge transport layer 60C are in contact with each other. Thus, in the light-emitting element 105, a drive voltage applied between the first electrode 20, which is an anode, and the second electrode 70, which is a cathode, can be set regardless of the thickness of the water-soluble resin layer 40E.

### Display Device

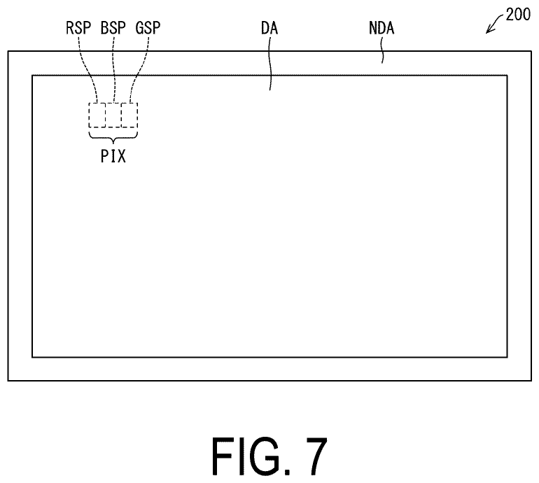

FIG. 7 is a plan view illustrating a schematic configuration of a display device 200.

As illustrated in FIG. 7, the display device 200 includes a frame region NDA and a display region DA. A plurality of pixels PIX are provided in the display region DA of the display device 200, and each pixel PIX includes a red subpixel RSP, a blue subpixel BSP, and a green subpixel GSP. In the present embodiment, a case will be described as an example in which the one pixel PIX includes the red subpixel RSP, the blue subpixel BSP, and the green subpixel GSP, but the present embodiment is not limited thereto, and the one pixel PIX may further include a subpixel of another color.

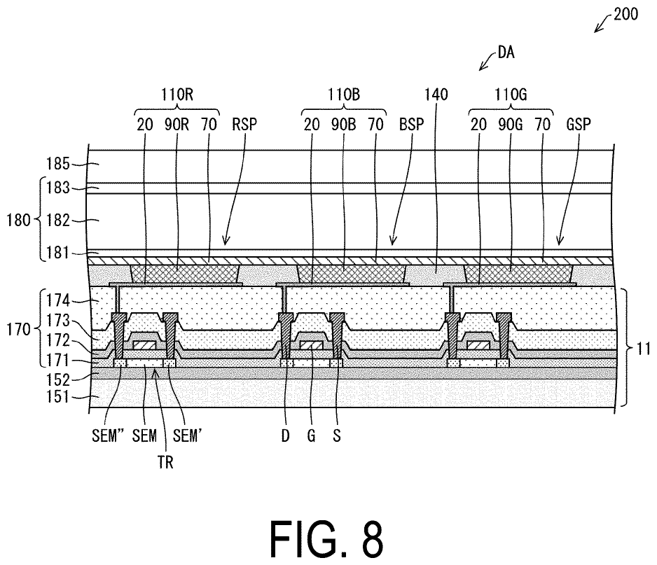

As illustrated in FIG. 8, the display device 200 includes a red subpixel RSP, a blue subpixel BSP, and a green subpixel GSP as light-emitting regions in the display region DA, the red subpixel RSP includes a light-emitting element 110R that emits red light, the blue subpixel BSP includes a light-emitting element 110B that emits blue light, and the green subpixel GSP includes a light-emitting element 110G that emits green light. The display region DA of the display device 200 includes a bank 140 surrounding each subpixel as a non-light-emitting region.

The light-emitting element 110R includes a function layer 90R including a light-emitting layer that emits red light between the first electrode 20 and the second electrode 70. The light-emitting element 110B includes a function layer 90B including a light-emitting layer that emits blue light between the first electrode 20 and the second electrode 70. The light-emitting element 110G includes a function layer 90G including a light-emitting layer that emits green light between the first electrode 20 and the second electrode 70. In each of the function layers 90R, 90B, and 90G, as illustrated in FIGS. 1 to 6, a first charge transport layer, a light-emitting layer, a second charge transport layer, and at least one water-soluble resin layer are layered between the first electrode 20 and the second electrode 70, and the water-soluble resin layer is in contact with at least a portion of the light-emitting layer.

Although a case in which the light-emitting element 110R that emits red light, the blue light-emitting element 110B that emits blue light, and the green light-emitting element 110G that emits green light are all quantum dot light-emitting diodes (QLEDs) is described as an example in the present embodiment, the disclosure is not limited to this. The light-emitting element 110R, the light-emitting element 110B, and the light-emitting element 110G may each independently be an organic light-emitting diode (OLED). In a case where the light-emitting elements are OLEDs, the light-emitting layer included in the light-emitting element of each color is, for example, an organic light-emitting layer formed by a vapor deposition method.

As illustrated in FIG. 8, in the display device 200, on a substrate 151, a barrier layer 152, a thin film transistor layer 170 including a transistor TR, the light-emitting element 110R that emits red light, the light-emitting element 110B that emits blue light, the light-emitting element 110G that emits green light, and a bank 140 (transparent resin layer), a sealing layer 180, and a function film 185 are provided in this order from the substrate 151 side. Note that as illustrated in FIG. 8, a substrate in which the barrier layer 152, the thin film transistor layer 170 including the transistor TR, and a plurality of first electrodes 20 are provided on the substrate 151 in this order from the substrate 151 side is referred to as a substrate (active matrix substrate) 11.

The substrate 151 may be, for example, a resin substrate made of a resin material such as a polyimide, or may be a glass substrate. In a case that the display device 200 is a non-flexible display device, the glass substrate can be used as the substrate 151.

The barrier layer 152 is a layer that prevents foreign matters such as water and oxygen from infiltrating into the transistor TR, the light-emitting element 110R, the light-emitting element 110B, and the light-emitting element 110G. The barrier layer 152 can be composed of, for example, a silicon oxide film, a silicon nitride film, or a silicon oxynitride film, or a layered film of these, formed by a CVD method. In the display device 200, each of the light-emitting element 110R, the light-emitting element 110B, and the light-emitting element 110G includes a water-soluble resin layer in each of the function layers 90R, 90B, and 90G, whereby moisture (dampness content) transmitted through the barrier layer 152 is prevented from infiltrating into the light-emitting layer.

The portion of the transistor TR in the thin film transistor layer 170 including the transistor TR includes a semiconductor film SEM and doped semiconductor films SEM′ and SEM″, an inorganic insulating film 171, a gate electrode G, an inorganic insulating film 172, an inorganic insulating film 173, a source electrode S, a drain electrode D, and a flattening film 174.

The semiconductor films SEM, SEM′ and SEM″ may be formed of low-temperature polysilicon (LTPS) or an oxide semiconductor (for example, an In—Ga—Zn—O based semiconductor), for example. Although a case in which the transistor TR has a top gate structure is exemplified in the present embodiment, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, and copper.

The inorganic insulating film 171, the inorganic insulating film 172, and the inorganic insulating film 173 can be composed of, for example, a silicon oxide film, a silicon nitride film, or a silicon oxynitride film, or a layered film thereof, formed by using the CVD method. The flattening film 174 can be made of a coatable organic material such as polyimide and acrylic.

The first electrodes 20 included in the light-emitting elements 110R, 110B, and 110G are provided in an upper layer above the flattening film 174, and the bank 140 (transparent resin layer) having an insulating property is provided to cover the edges of the plurality of first electrodes 20. The bank 140 constitutes the non-light-emitting region in the display region DA, and can be formed through patterning by a photolithography method after applying an organic material such as polyimide or acrylic, for example.

The sealing layer 180 is a translucent film and, for example, can be composed of an inorganic sealing film 181 covering the second electrode 70, an organic film 182 that is an upper layer above the inorganic sealing film 181, and an inorganic sealing film 183 that is an upper layer above the organic film 182. The sealing layer 180 prevents a foreign matter such as water or oxygen from infiltrating into the light-emitting elements 110R, 110B, 110G. In the display device 200, each of the function layers 90R, 90B, and 90G is provided with a water-soluble resin layer, whereby moisture transmitted through the sealing layer 180 is prevented from infiltrating into the light-emitting layer.

The function film 185 is a film having at least one of an optical compensation function and a protection function, for example.

### Display Device 210 According to One Modified Example

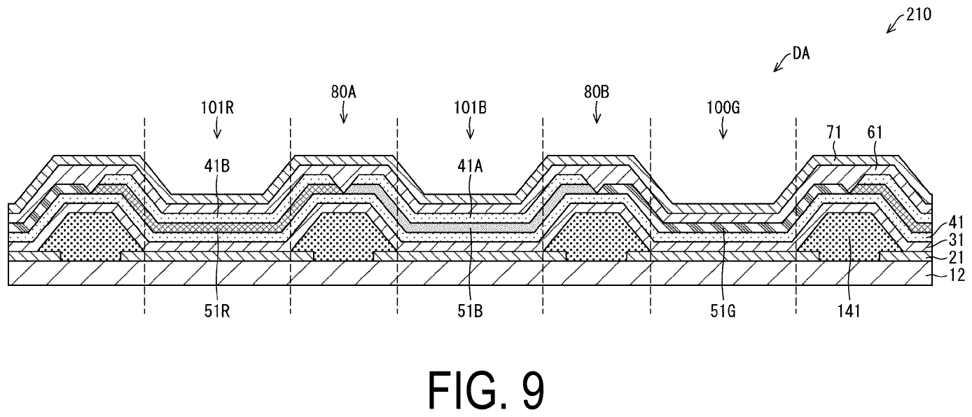

The display device according to an embodiment of the disclosure is not limited to the embodiment described above. For example, as illustrated in FIG. 9, a display device 210 according to one embodiment includes a display region DA in which light-emitting elements 101R, 101B, and 100G are manufactured through a series of steps.

The light-emitting elements 101R, 101B, and 100G and a bank 141 in non-light-emitting regions 80A and 80B are formed on a substrate 12 provided with first electrodes 21. The substrate 12 including the first electrodes 21 may be the above-described active matrix substrate.

In the light-emitting elements 101R, 101B, and 100G, each of edge portions of the plurality of first electrodes 21 is insulated by the bank 141. Each of the first electrodes 21 is an anode. Each of the light-emitting elements 101R, 101B, and 100G shares a first charge transport layer 31 which is formed in one step and is continuous in the display region DA, and the first charge transport layer 31 may be a hole transport layer. The light-emitting elements 101R, 101B, and 100G share a water-soluble resin layer 41 that is formed in one step and is continuous in the display region DA. Similarly, the light-emitting elements 101R, 101B, and 100G share a second charge transport layer 61 and a second electrode 71 which is a cathode, which are formed in one step in the display region DA and are continuous. The second charge transport layer 61 is an electron transport layer.

In the display device 210, the light-emitting element 101R includes the first electrode 21, the first charge transport layer 31, the water-soluble resin layer 41 which is a water-soluble resin layer of a first layer, the light-emitting layer 51R, the water-soluble resin layer 41B which is a water-soluble resin layer of a second layer, the second charge transport layer 61, and the second electrode 71 in this order in the light-emitting region. The light-emitting element 101B includes the first electrode 21, the first charge transport layer 31, the water-soluble resin layer 41 of a first layer, the light-emitting layer 51B, the water-soluble resin layer 41A of a second layer, the second charge transport layer 61, and the second electrode 71 in this order in the light-emitting region. The light-emitting element 100G includes the first electrode 21, the first charge transport layer 31, the water-soluble resin layer 41A of a first layer, the light-emitting layer 51G, the second charge transport layer 61, and the second electrode 71 in this order in the light-emitting region.

In the display device 210, thicknesses of the water-soluble resin layer 41A, the water-soluble resin layer 41B, and the water-soluble resin layer 41 may be adjusted to adjust a carrier gap depending on the type of the light-emitting material contained in each of the light-emitting layer 51R, the light-emitting layer 51B, and the light-emitting layer 51G.

In the display device 210, an outer peripheral end portion including an outer peripheral end surface of the light-emitting layer 51R and an outer peripheral end portion including an outer peripheral end surface of the light-emitting layer 51B are provided on the non-light-emitting region 80B, and an outer peripheral end portion including an outer peripheral end surface of the light-emitting layer 51B and an outer peripheral end portion including an outer peripheral end surface of the light-emitting layer 51G are provided on a non-light-emitting region 80A. In the display device 210, an end surface of each of the light-emitting layer 51R, the light-emitting layer 51B, and the light-emitting layer 51G is provided on the non-light-emitting region 80A or 80B, whereby a light-emitting material of another light-emitting layer is prevented from being mixed in the light-emitting region. In addition, the light-emitting layer 51R, the light-emitting layer 51B, and the light-emitting layer 51G are provided not only in the light-emitting region but also in a wide range including the non-light-emitting regions 80A and 80B, whereby a film of the quantum dots, which are light-emitting materials, is formed to have a uniform thickness in the light-emitting region.

### Display Device 220 According to One Modified Example

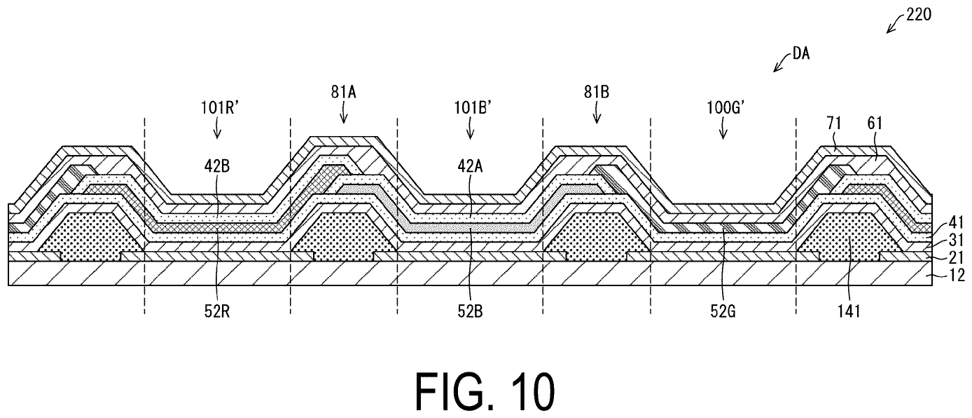

The display device according to an embodiment of the disclosure is not limited to the embodiment described above. For example, as illustrated in FIG. 10, a display device 220 according to one embodiment includes light-emitting elements 101R′, 101B′, and 100G′, the light-emitting element 101R′ includes a light-emitting layer 52R that emits red light, the light-emitting element 101B′ includes a light-emitting layer 52B that emits blue light, and the light-emitting element 100G′ includes a light-emitting layer 52G that emits green light. In the display device 220 according to the embodiment, the light-emitting elements 101R′, 101B′, and 100G′ are provided as a light-emitting region by a series of steps.

The light-emitting elements 101R′, 101B′, and 100G′ include first electrodes 21 which are anodes independent of each other in the display region DA, and share a first charge transport layer 31, a water-soluble resin layer 41, a second charge transport layer 61, and a second electrode 71 which are formed in one step and are continuous. The first charge transport layer 31 is a hole transport layer, the second charge transport layer 61 is an electron transport layer, and the second electrode 71 is a cathode.

In the display device 220, in a non-light-emitting region 81A surrounding the light-emitting elements 101R′, 101B′, and 100G′, an outer peripheral end portion including an outer peripheral end surface of the light-emitting layer 52B, a water-soluble resin layer 42A, and an outer peripheral end portion including an outer peripheral end surface of the light-emitting layer 52R are overlapped in this order, whereby the light-emitting layer 52R and the light-emitting layer 52B are not in direct contact with each other. In the non-light-emitting region 81A, the outer peripheral end portion of the light-emitting layer 52R is covered with a water-soluble resin layer 42B.

In addition, in the display device 220, in a non-light-emitting region 81B, an outer peripheral end portion including an outer peripheral end surface of the light-emitting layer 52G, the water-soluble resin layer 42A, and the outer peripheral end portion including the outer peripheral end surface of the light-emitting layer 52B overlap with each other, whereby the light-emitting layer 52B and the light-emitting layer 52G are not in direct contact with each other.

In the display device 220 according to the embodiment, the outer peripheral end portion of the light-emitting layer 52R and the outer peripheral end portion of the light-emitting layer 52B are separated by the water-soluble resin layer 42A, the outer peripheral end portion of the light-emitting layer 52B and the outer peripheral end portion of the light-emitting layer 52G are separated by the water-soluble resin layer 41A, and the outer peripheral end portion of the light-emitting layer 52G is covered by the water-soluble resin layer 42B. As a result, the light-emitting layer 52R, the light-emitting layer 51B, and the light-emitting layer 51G are provided not only in the light-emitting region but also in a wide range including the non-light-emitting regions 81A and 81B, whereby a film of the quantum dots, which are light-emitting materials, is formed to have a uniform thickness in the light-emitting region. In addition, in the display device 220, the outer peripheral end portions of the light-emitting layers 51R, 51B, and 51G are not in contact with each other in the non-light-emitting regions 81A and 81B, and thus the light-emitting materials for forming the light-emitting layers 51R, 51B, and 51G are not mixed in color in the light-emitting region.

### Method for Manufacturing Light-Emitting Element

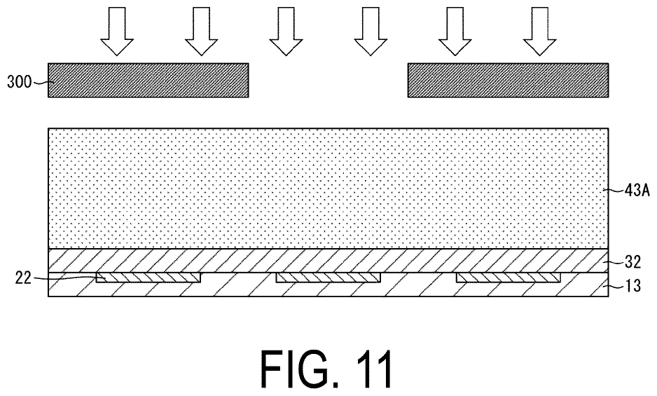

A method for manufacturing a light-emitting element and a display device according to an embodiment of the disclosure will be described with reference to FIGS. 11 to 25. As illustrated in FIGS. 11 to 25, a method for manufacturing a light-emitting element and a display device according to an embodiment of the disclosure includes (i) a step of applying a water-soluble resin composition (composition) including a water-soluble resin and a positive-working photosensitizer to form a water-soluble resin layer, (ii) a step of exposing the water-soluble resin layer to light to develop a pattern, (iii) a step of forming a light-emitting layer on the developed pattern, and (iv) a step of peeling and developing the light-emitting layer on the pattern by peeling a portion of the water-soluble resin layer, and manufactures a light-emitting element 101B″ on a substrate 13. In addition, the steps of (i) to (iv) are repeated to manufacture a display device 230 including a plurality of light-emitting elements 101B″, 101R″, and 100G″ on the substrate 13.

Hereinafter, a manufacturing method will be described in which a pattern of the light-emitting layer is formed by exposing a portion of the water-soluble resin layer to light to develop the pattern on the portion of the water-soluble resin layer without exposing a portion other than the portion. However, the method for manufacturing a light-emitting element and a display device according to an embodiment of the disclosure is not limited to the manufacturing method in which only a portion of the composition is exposed to light. The water-soluble resin layer may be composed not only of the exposed portion but also of an unexposed portion. That is, the water-soluble resin layer is a layer formed by applying at least a composition for forming the water-soluble resin layer, and whether or not the composition is exposed to light is not an essential configuration. Although not illustrated, the entire surface of the composition for forming the water-soluble resin layer may be exposed to light or need not be exposed to light after the composition is applied.

As illustrated in FIG. 11, a first electrode 22 is formed on the substrate 13 for forming the water-soluble resin layer by a general electrode forming method. The first electrode 22 may be an electrode material that reflects visible light, and a general electrode forming method can be used as a film formation method of the first electrode 22. Examples thereof include physical vapor deposition (PVD) methods such as a vacuum vapor deposition method, a sputtering method, an electron beam (EB) vapor deposition method, and an ion plating method, or a chemical vapor deposition (CVD) method. Furthermore, a method of patterning the first electrode 22 is not limited, and examples thereof include a photolithography method and an ink-jet method.

Although not illustrated, a bank having an insulating property may be formed between the first electrodes 22 on the substrate 13.

In a case where a hole injection layer is formed as a first charge transport layer 32 on the substrate 13, a dispersion liquid containing the above-described nanoparticles of NiO or the like as a hole injection material and a polar solvent such as water, ethanol, or dimethyl sulfoxide is prepared, and the dispersion liquid only need be applied to form the hole injection layer.

In a case where a hole transport layer is formed as the first charge transport layer 32 on the substrate 13, a composition containing the above-described photosensitive hole transport material and a photoacid generator is prepared, and the composition only need be applied to form the hole transport layer. Examples of the photoacid generator include triphenylsulfonium salts and diphenyliodonium salts which have fluoroalkylsulfonic acid as an anion.

The dispersion liquid or the composition for forming the first charge transport layer 32 may be collectively applied to subpixels in a plurality of light-emitting elements by a spin coating method, or may be separately applied to each subpixel by an ink-jet method or the like. In a case where the first charge transport layer 32 contains a photosensitive hole transport material, the photosensitive hole transport material is preferably cured by exposure to light after being applied onto the substrate 13.

FIG. 11 is a diagram schematically illustrating steps from a step of forming a water-soluble resin layer 43A to a step of exposing the water-soluble resin layer 43A to light.

The water-soluble resin layer 43A is formed using a water-soluble resin composition for forming a water-soluble resin layer. The water-soluble resin composition may contain the above-described water-soluble resin, a positive-working photosensitizer, a solvent, and water. The water-soluble resin is as described in the section of the water-soluble resin layer included in the light-emitting element.

The water-soluble resin composition only need contain 1 to 500 parts by mass of the positive-working photosensitizer per 100 parts by mass of the water-soluble resin as a solid content.

The positive-working photosensitizer contained in the water-soluble resin composition only need be, for example, a compound which is decomposed (also referred to as depolymerized) by irradiation with light to generate a proton (H⁺) and an organic compound having an acid group such as a carboxylic acid group or a sulfonic acid group. Examples of the organic compound having a carboxylic acid group include indenecarboxylic acid, phthalic acid, and derivatives thereof. The positive-working photosensitizer may typically be a diazoquinone compound. Thus, the positive-working photosensitizer will be described below by using a diazoquinone compound which is a typical example. Examples of the diazoquinone compound include diazoquinones such as diazobenzoquinone (DBQ) and diazonaphthoquinone (DNQ), and derivatives thereof.

The diazoquinone derivative only need be, for example, a compound in which a diazoquinone moiety and a residue derived from a compound having a hydroxyl group or an amino group are bonded via an ester bond or an amide bond. Here, the diazoquinone moiety only need have, for example, a sulfonyl group for forming an ester bond or an amide bond. The diazoquinone compound may be a compound having an ester bond or an amide bond derived from a sulfonyl group of the diazoquinone moiety and a hydroxyl group or an amino group of a compound. Here, the residue derived from a compound having a hydroxyl group means an alcohol residue, and the residue derived from a compound having an amino group means an amine residue.

In a case where the compound forming an ester bond or an amide bond with the diazoquinone moiety has a divalent or higher hydroxyl group or amino group, a conversion rate of the hydroxyl group or amino group of the compound by the diazoquinonesulfonyl moiety is preferably 30% or more. In addition, although it should not be limited, the conversion rate of the hydroxyl group or the amino group of the compound by the diazoquinone moiety may be substantially 100 mol %. This makes it possible to suitably control the solubility of the water-soluble resin layer in a developer before and after exposure to light. The conversion rate by the diazoquinone moiety is defined as a conversion rate of a hydroxyl group contained in the compound into an ester bond or a conversion rate of an amino group contained in the compound into an amide bond, and is calculated by the following formula.

$$( Number of moles of diazoquinone moiety ) / ( number of moles of hydroxyl group and amino group of compound before conversion by diazoquinone moiety ) \times 100$$

Examples of the derivative of diazoquinone include a diazoquinone sulfonic acid ester and diazoquinone sulfonic acid amide.

Examples of the diazoquinone sulfonic acid ester include diazobenzoquinone compounds such as 1,2-benzoquinone diazo-4-sulfonic acid ester and 1,2-benzoquinone diazo-5-sulfonic acid ester, and diazonaphthoquinone compounds such as 1,2-naphthoquinone diazo-5-sulfonic acid ester and 1,2-naphthoquinone diazo-4-sulfonic acid ester. The diazoquinone sulfonic acid derivative may be diazo-coupled.

Examples of the diazoquinone derivative include a diazoquinone derivative in which hydrogen constituting a part of a hydroxyl group or an amino group of a compound having the hydroxyl group or the amino group is converted by the diazoquinonesulfonyl moiety.

In the diazoquinone compound, examples of a compound for forming a residue (alcohol residue) derived from a compound having a hydroxyl group include a compound having a phenolic hydroxyl group. The compound having a phenolic hydroxyl group may be a phenol having a monovalent hydroxyl group such as phenol or naphthol, a phenol having a divalent or higher hydroxyl group such as catechol or pyrogallol, a phenol having a divalent or higher phenolic hydroxyl group such as bisphenol, trisphenol or tetrakisphenol, or a phenol resin such as a novolac-type phenol resin. Examples of the compound having a phenolic hydroxyl group include 4,4′,4″-ethylidinetrisphenol, 2,3,4-trihydroxybenzophenone, 2,3,4,4′-tetrahydroxybenzophenone, α,α-bis(4-hydroxyphenyl)-4-(4-hydroxy-α,α-dimethylbenzyl)-ethylbenzene, 4,4′-(1-{4-[1-(4-hydroxyphenyl)-1-methylethyl]phenyl}ethylidene)diphenol, and a novolac-type cresol resin.

Examples of the diazoquinone sulfonamide include a compound in which a 1,2-benzoquinone diazo 4-sulfonyl group or the like is introduced into an amino group introduced into a resin by an ester bond between a hydroxyl group of an amino alcohol and a resin having a carboxyl group to form sulfonamide.

Examples of the solvent contained in the composition for forming the water-soluble resin layer include water, alcohols such as ethanol, isopropyl alcohol (IPA), and ethylene glycol, polar solvents such as N-methylpyrrolidone (NMP) and dimethyl sulfoxide (DMSO), nitriles such as acetonitrile, ketones such as acetone and methyl ethyl ketone, and polyethylene glycol monomethyl ether acetate (PEGMEA).

The positive-working photosensitizer contained in the composition for forming the water-soluble resin layer is not limited to the diazoquinone compound. The positive-working photosensitizer only need be, for example, at least one positive-working photosensitizer selected from the group consisting of the above-described diazoquinone compound, polyolefin sulfone, and polyphthalaldehyde. The polyolefin sulfone only need be a photosensitive polyolefin sulfone having photosensitivity, and may be, for example, a polyolefin sulfone in which a dye that generates an amine by absorbing light is introduced into a side chain of the polyolefin sulfone via a carbon bonded to a sulfone group in a polyolefin sulfone chain. In addition, the polyphthalaldehyde only need be any polyphthalaldehyde having photosensitivity, and examples thereof include photosensitive polyphthalaldehydes such as polyphthalaldehyde (PPA) and a polyphthalaldehyde having an oxime ether terminal.

Besides, the composition for forming the water-soluble resin layer may contain, as additives, for example, a photosensitizer such as acetophenone, a chemical sensitizer, a filler, a coloring agent, a stabilizer such as an antioxidant, and a surfactant such as a leveling agent, an antifoaming agent, or a dispersant.

Further, the composition for forming the water-soluble resin layer may contain a crosslinking agent. The crosslinking agent may be a crosslinking agent that is crosslinked by an acid generated when the diazoquinone compound contained in the composition for forming the water-soluble resin layer is exposed to light, and examples thereof include a novolac-type phenol resin, an epoxy resin, a melamine resin, an unsaturated polyester resin, a polyimide resin, diallyl phthalate, and a urethane resin. Thus, the degree of crosslinking can be controlled by controlling the content of the crosslinking agent and the firing conditions at the time of forming a photoresist layer, and the control of the solubility due to this exhibits an effect of being capable of obtaining a pattern with higher accuracy. The content of the crosslinking agent in the composition for forming the water-soluble resin layer should not be limited, but only need be, for example, more than 0 parts by mass, and is preferably 100 parts by mass or less, and more preferably 50 parts by mass or less, per 100 parts by mass of the total of the water-soluble resin and the diazoquinone compound.

The composition for forming the water-soluble resin layer is collectively applied to subpixels in the plurality of light-emitting elements by a dip coating method or a spin coating method, thereby providing the water-soluble resin layer 43A. Thereafter, the water-soluble resin layer 43A only need be heated and dried, for example, at a temperature in a range of 80 to 150° C. In addition, the composition for forming the water-soluble resin layer is not limited to being collectively applied to the subpixels, and may be separately applied to each subpixel by, for example, an ink-jet method or the like.

Thereafter, as illustrated in FIG. 11, the water-soluble resin layer 43A formed on the first charge transport layer 32 is preferably exposed to light using a photomask 300 having a desired pattern. Examples of the light for exposing the water-soluble resin layer 43A include an ultraviolet ray having a wavelength of about 150 to 450 nm and an electron beam. The ultraviolet ray may be a g-line (wavelength 436 nm), an h-line (wavelength 405 nm), or an i-line (wavelength 365 nm) from a high-pressure mercury lamp, or may be an excimer laser (wavelength 150 to 248 nm). When the water-soluble resin layer 43A is exposed to light, the thickness t1 of the water-soluble resin layer 43A only need be adjusted by designing the wavelength and the amount of exposure. The amount of exposure is not limited, but only need be, for example, in a range of 1 mJ/cm² to 1000 mJ/cm².

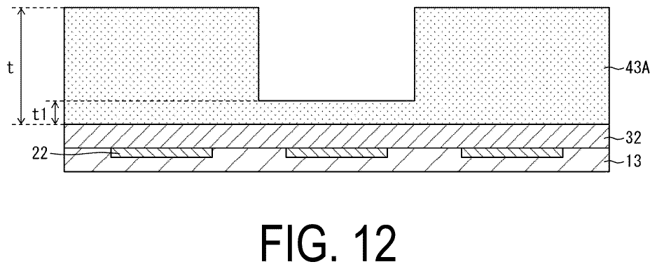

FIG. 12 is a diagram schematically illustrating a step of cleaning the water-soluble resin layer 43A with a developer and developing a pattern in an exposed portion of the water-soluble resin layer 43A. In the water-soluble resin layer 43A, an acidic compound such as an indenecarboxylic acid derivative is generated in the exposed portion, thereby enhancing the solubility in an alkaline aqueous developer. Thus, a desired pattern can be developed on the water-soluble resin layer 43A by washing with an alkaline aqueous developer. The desired pattern can be developed by, for example, immersing the water-soluble resin layer 43A in a beaker (not illustrated) storing a developer. The developer may be supplied to the water-soluble resin layer 43A by, for example, spraying the developer using a spray nozzle or the like.

Examples of the developer include an alkaline aqueous developer and an organic solvent developer, and an alkaline aqueous developer is preferable. Examples of the alkaline aqueous developer include aqueous developers containing alkalis such as potassium hydroxide (KOH) and tetramethylammonium hydroxide (TMAH).

The water-soluble resin layer 43A after developing may be heated and dried, for example, at a temperature of 50 to 150° C. The water-soluble resin layer 43A has a thickness t of about 100 nm to 5000 nm at an unexposed portion, and the thickness t of the water-soluble resin layer 43A only need be adjusted by, for example, the applied amount of the composition for forming the water-soluble resin layer. The thickness t1 at the exposed portion is adjusted to be 20 nm or less. As described above, the thickness t1 only need be adjusted by the amount of exposure when the water-soluble resin layer 43A is exposed to light.

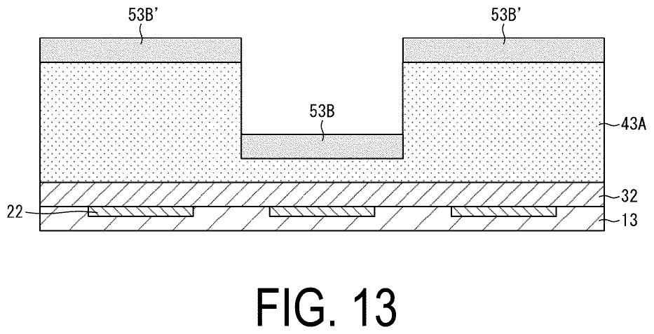

FIG. 13 is a diagram schematically illustrating a step of forming a light-emitting layer 53B on the pattern formed on the water-soluble resin layer 43A. The light-emitting layer 53B can be formed by applying a composition containing a light-emitting material onto the water-soluble resin layer 43A. The light-emitting layer 53B is not different from a light-emitting layer 53B′ provided in the unexposed portion except that the light-emitting layer 53B is formed in the exposed portion of the water-soluble resin layer 43A. In the step of forming the light-emitting layer, it is only necessary to form the light-emitting layer 53B, and the light-emitting layer 53B′ need not necessarily formed. The water-soluble resin layer 43A is a first water-soluble resin layer at a portion in contact with the back surface of the light-emitting layer 53B.

The light-emitting layer can be film-formed by separately patterning for each subpixel by using a dispersion liquid in which quantum dots are dispersed by a spin coating method, an ink-jet method, or the like. The dispersion liquid of quantum dots contains a solvent such as hexane, toluene, or phenylcyclohexane, and may be mixed with a dispersion material such as thiol or amine.

In a case where the light-emitting material of the light-emitting layer contains a quantum dot having a shell of a metal sulfide which is a sulfide semiconductor as an inorganic ligand, the quantum dot only need be produced in an inert gas atmosphere as follows.

First, to obtain a precursor of the sulfide semiconductor, a dispersion liquid containing a metal acetate, a metal nitrate, a metal halide, or the like as a metal source and thiourea, N-methylthiourea, or 1,3-dimethylthiourea as a sulfur source is prepared. The dispersion liquid may contain, as a precursor, a metal complex in which thiourea, N-methylthiourea, 1,3-dimethylthiourea, N,N′-dimethylthiourea, tetramethylthiourea, or thioacetamide is coordinated to a metal atom.

Next, a polar solvent in which halide ions in an excessive amount relative to the quantum dots are dissolved is mixed with a non-polar solvent in which the quantum dots to which carbon chains as organic ligands are coordinated are dispersed, and the organic ligands of the quantum dots are substituted with halide ions. Subsequently, the dispersion liquid of the precursor of the sulfide semiconductor and the dispersion liquid of the quantum dots in which the organic ligands are substituted with the halide ions are mixed and stirred.

The polar solvent for producing the quantum dots may contain, for example, at least one of polar solvents such as dimethyl sulfoxide (DMSO) and N,N-dimethylformamide (DMF), esters or lactones such as methyl acetate, ethers such as tetrahydrofuran, tetrahydrothiophene, and diethyl sulfide. The non-polar solvent is desirably, for example, toluene, hexane, octane, octadecene, or the like, and is preferably a non-polar solvent which is not mixed with the polar solvent for producing the quantum dots.

In a case where the polar solvent in the dispersion liquid of the precursor of the sulfide semiconductor and the non-polar solvent in the dispersion liquid of the quantum dots substituted with the halide ions are separated into two phases, the quantum dots each including a shell of the sulfide semiconductor as the inorganic ligand can be generated in the phase of the polar solvent.

The dispersion liquid of the polar solvent containing the quantum dots is applied onto the water-soluble resin layer 43A, and the layered body is heated at 80° C. to 500° C. to form a light-emitting layer containing the quantum dots each having a shell of the sulfide semiconductor as an inorganic ligand.

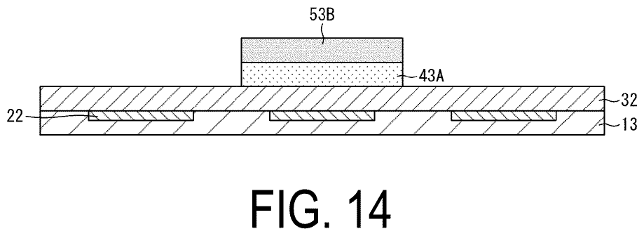

FIG. 14 is a diagram schematically illustrating a step of peeling and developing the light-emitting layer 53B by peeling off the water-soluble resin layer 43A other than the pattern provided on the water-soluble resin layer 43A. In the peeling and developing step, the light-emitting layer 53B′ is peeled off from the substrate 13 by the developer together with the unexposed portion of the water-soluble resin layer 43A. Thus, the light-emitting layer 53B is developed into a desired pattern on the water-soluble resin layer 43A.

Examples of the developer to be used in the peeling and developing step include an alkaline developer and an organic solvent developer, and an organic solvent developer is preferably used. As the organic solvent developer, a solvent contained in the composition for forming the water-soluble resin layer described above can be used, and examples thereof include organic solvents such as propylene glycol monomethyl ether acetate (PGMEA), acetone, isopropyl alcohol (IPA), dimethyl sulfoxide (DMSO), N,N-dimethylformamide (DMF), and N-methyl-2-pyrrolidone (NMP). When the organic solvent developer is used as the developer, the portion of the water-soluble resin layer 43A, which contains the positive-working photosensitizer, can be successfully peeled off together with the light-emitting layer 53B′, and the light-emitting layer 53B can be developed to have a desired pattern.

As illustrated in FIG. 14, when the light-emitting layer 53B and the water-soluble resin layer 43A in contact with the back surface of the light-emitting layer 53B are formed after peeling and developing, it can be expected that the water-soluble resin layer 43A prevents moisture from infiltrating into the light-emitting layer 53B even when moisture is enclosed in the first charge transport layer 32 in the manufacturing process of the first charge transport layer 32.

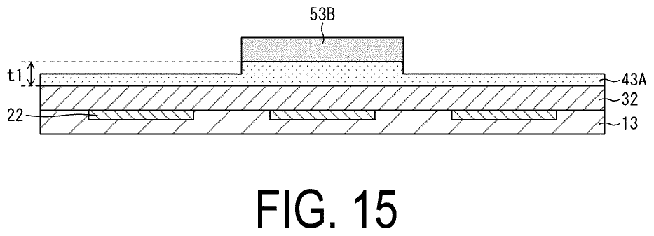

The developer may be supplied to the water-soluble resin layer 43A by immersion in a beaker storing the developer (developer tank) or by spraying the developer using a spray nozzle or the like. For example, as illustrated in FIG. 15, the thickness of the unexposed portion of the water-soluble resin layer 43A only need be adjusted depending on the thickness t1. The thickness of the unexposed portion of the water-soluble resin layer 43A only need be adjusted by adjusting the time for immersion in the beaker storing the developer or the amount of the developer supplied using a spray nozzle or the like.

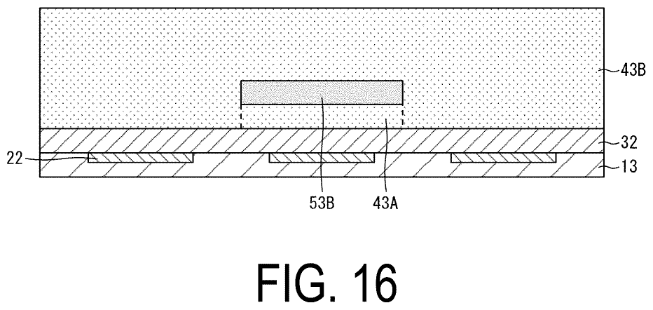

FIG. 16 is a diagram schematically illustrating a step of forming a water-soluble resin layer 43B (a second step of forming a water-soluble resin layer).

The composition of a water-soluble resin composition for forming the water-soluble resin layer 43B may be the same as or different from the composition of the water-soluble resin composition for forming the water-soluble resin layer 43A. For example, the mass average molecular weight of the water-soluble resin contained in the water-soluble resin composition for forming the water-soluble resin layer 43B is preferably larger than the mass average molecular weight of the water-soluble resin contained in the water-soluble resin layer 43A. Thus, the light-emitting layer 53B can be successfully protected by the water-soluble resin layer 43B from the developer supplied in the subsequent steps.

The method of applying the water-soluble resin composition for forming the water-soluble resin layer 43B is the same as the method of applying the composition for forming the water-soluble resin layer 43A, and thus the description thereof is omitted.

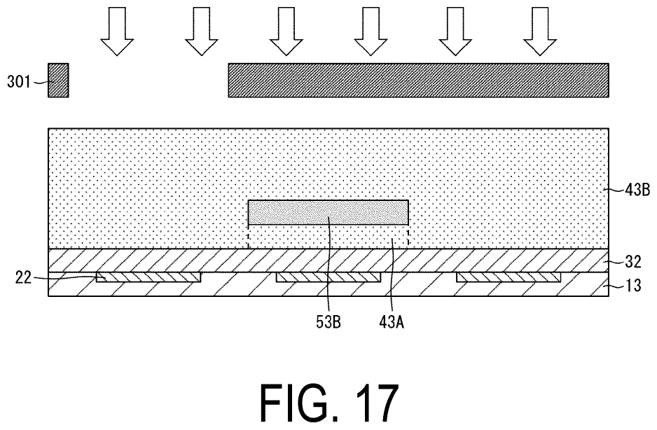

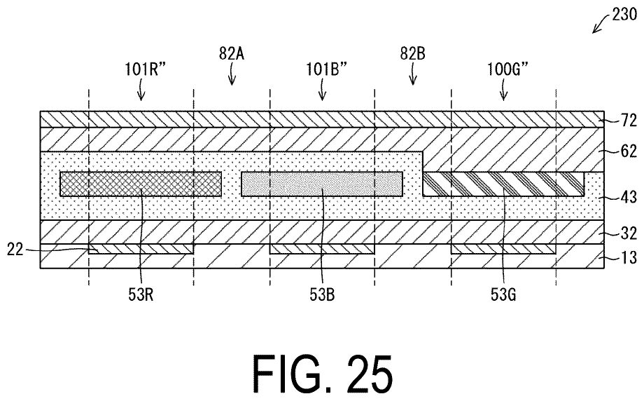

FIG. 17 is a diagram schematically illustrating steps from the step of forming the water-soluble resin layer 43B to a step of exposing the water-soluble resin layer 43B to light. The water-soluble resin layer 43B is exposed to light through a photomask 301 having a pattern different from that of the photomask 300. To be more specific, in the display region DA on the substrate 13, as illustrated in FIG. 25, exposure is performed to form a pattern which does not overlap with at least the light-emitting region of the light-emitting elements 101B″. The conditions for the exposure are the same as those in the first exposure step, and thus the description thereof is omitted.

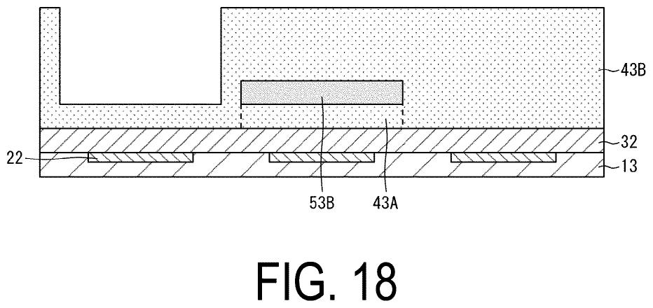

FIG. 18 is a diagram schematically illustrating a step (second developing step) of cleaning the water-soluble resin layer 43B with the developer after the second exposure and developing a pattern in the exposed portion of the water-soluble resin layer 43B. A peeling liquid for developing the water-soluble resin layer 43B is preferably an alkaline aqueous developer as in the first developing step. In the second developing step, the front surface of the light-emitting layer 53B is protected from the alkaline aqueous developer by being covered with the water-soluble resin layer 43B.

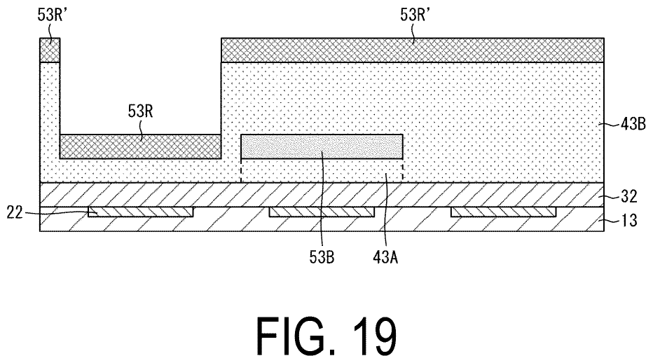

FIG. 19 is a diagram schematically illustrating a step of forming a light-emitting layer 53R on a pattern provided in the water-soluble resin layer 43B. The light-emitting layer 53R is formed by applying a composition containing a light-emitting material that emits red light onto the water-soluble resin layer 43B. A light-emitting layer 53R′ is not different from the light-emitting layer 53R except that the light-emitting layer 53R′ is formed in the unexposed portion of the water-soluble resin layer 43B.

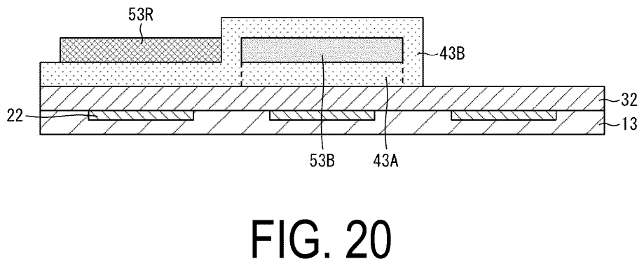

FIG. 20 is a diagram schematically illustrating a step of peeling and developing the light-emitting layer 53R (a second peeling and developing step). In the second peeling and developing step, the unexposed portion of the water-soluble resin layer 43B only need be peeled off together with the light-emitting layer 53R′ while leaving a portion of the water-soluble resin layer 43B to cover the light-emitting layer 53B. As a result, the light-emitting layer 53R can be developed into a desired pattern, and the portion of the water-soluble resin layer 43B can be made to serve as the second water-soluble resin layer in contact with the front surface of the light-emitting layer 53R. In addition, the light-emitting layer 53B can be protected by the water-soluble resin layer 43B from a developer to be used in a subsequent step.

The developer to be used in the second peeling and developing step and the peeling and developing conditions are the same as those in the first peeling and developing step, and thus the description thereof is omitted.

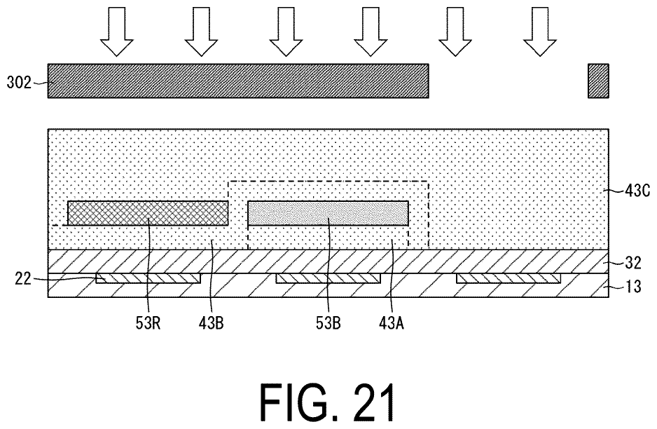

FIG. 21 is a cross-sectional view schematically illustrating steps from a step of forming a water-soluble resin layer 43C to a step of exposing the water-soluble resin layer 43C to light. The water-soluble resin layer 43C is exposed to light through a photomask 302 having a pattern different from that of the photomasks 300 and 301. To be more specific, in the display region DA on the substrate 13, as illustrated in FIG. 25, exposure is performed to form a pattern which does not overlap with at least the light-emitting regions of the light-emitting element 101B″ and the light-emitting element 101R″. The conditions for the exposure are the same as those in the first exposure step, and thus the description thereof is omitted. The composition for forming the water-soluble resin layer 43C may have the same composition as the compositions for forming the water-soluble resin layers 43A and 43B or may have a different composition. For example, the mass average molecular weight of the water-soluble resin contained in the composition for forming the water-soluble resin layer 43C is preferably larger than that of the water-soluble resin contained in the water-soluble resin layer 43A, similarly to the water-soluble resin contained in the water-soluble resin layer 43B.

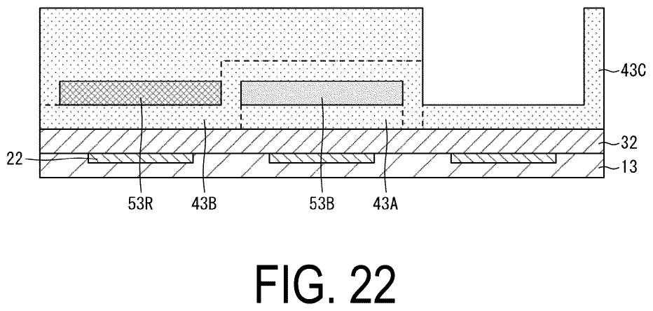

FIG. 22 is a diagram schematically illustrating a step (third developing step) of cleaning the water-soluble resin layer 43C after exposure to light with a developer and developing a pattern on the water-soluble resin layer 43C. A peeling liquid for developing the water-soluble resin layer 43C is preferably an alkaline aqueous developer. The water-soluble resin layer 43B covers the front surface of the light-emitting layer 53B and the water-soluble resin layer 43C covers the front surface of the light-emitting layer 53R, and thus the light-emitting layer 53R and the light-emitting layer 53B are protected from the alkaline aqueous developer for developing the water-soluble resin layer 43C.

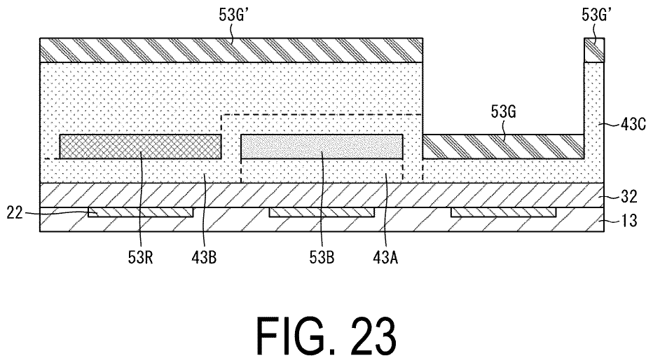

FIG. 23 is a diagram schematically illustrating a step of forming a third light-emitting layer 53G. The light-emitting layer 53G is formed by applying a dispersion liquid containing a light-emitting material that emits green light onto the water-soluble resin layer 43C. The preparation of the dispersion liquid containing the light-emitting material for forming the light-emitting layer 53G is in line with the preparation of the dispersion liquid containing the light-emitting material for forming the light-emitting layer 53B, and thus description thereof is omitted. In addition, a light-emitting layer 53G′ is not different from the light-emitting layer 53G except that the light-emitting layer 53G′ is formed in an unexposed portion of the water-soluble resin layer 43C. As illustrated in FIG. 23, the water-soluble resin layer 43C is formed as a first water-soluble resin layer in contact with the back surface of the light-emitting layer 53G, and is formed as a second water-soluble resin layer in contact with the front surface of the light-emitting layer 53R.

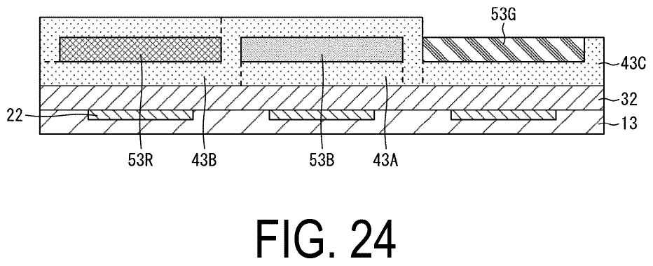

FIG. 24 is a diagram schematically illustrating a step (third developing step) of cleaning the water-soluble resin layer 43C with a developer and developing the light-emitting layer 53G on the pattern of the water-soluble resin layer 43C. In the peeling and developing for developing the light-emitting layer 53G, the peeling and developing only need be performed in such a manner to leave a portion of the water-soluble resin layer 43C and cover the light-emitting layer 53R with the water-soluble resin layer 43C. This allows the water-soluble resin layer 43C to serve as the second water-soluble resin layer in contact with the front surface of the light-emitting layer 53R while developing a desired pattern on the light-emitting layer 53G. Thus, the light-emitting layer 53R can be prevented from being exposed to the developer by the water-soluble resin layer 43C.

As illustrated in FIG. 25, the display device 230 according to an embodiment of the disclosure is manufactured by forming a second charge transport layer 62, which is an electron transport layer, and a second electrode 72, which is a cathode, on the substrate 13 on which the light-emitting layers 53R, 53B, and 53G are formed.

The display device 230 includes light-emitting elements 101R″, 101B″, and 100G″ constituting a light-emitting region, and includes non-light-emitting regions 82A and 82B between the light-emitting elements. In the non-light-emitting regions 82A and 82B, the outer peripheral end surfaces of the light-emitting elements 101R″, 101B″, and 100G″ constituting the light-emitting region are not in contact with each other with the water-soluble resin layer 43 interposed therebetween. The widths of the light-emitting elements 101R″, 101B″, and 100G″ only need be adjusted by the pattern of the photomask to be used when the water-soluble resin layer 43 is formed.

A composition to be used for forming the second charge transport layer 62 which is an electron transport layer only need be a composition containing the above-described electron transporting material, and the composition may be collectively applied onto subpixels of a plurality of light-emitting elements over the substrate 13 over which the light-emitting layers 53R, 53B, and 53G are formed by a spin coating method, a dip coating method, or the like, or may be separately applied onto each of the subpixels by an ink-jet method or the like.

A general electrode forming method can be used as a film formation method of the second electrode 72, and examples thereof include physical vapor deposition (PVD) methods such as a vacuum vapor deposition method, a sputtering method, an electron beam (EB) vapor deposition method, and an ion plating method, or a chemical vapor deposition (CVD) method.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

An example of the disclosure will be described below.

### Preparation of Resin Composition

Water-soluble resin compositions for forming water-soluble resin layers of Samples 1 to 5 were prepared using the materials shown in the following [Materials] section.

### Materials

### Water-Soluble Resin

PVA-PVP graft copolymer A-1
   PVA ratio: 0.3
PVA-PVP graft copolymer A-2
   PVA ratio 0.4
PVA-PVP graft copolymer A-3
   PVA ratio 0.5
PVA-PVP graft copolymer B-1
   PVA ratio: 0.6
PVA-PVP graft copolymer B-2
   PVA ratio: 0.7
PVA-PVP graft copolymer B-3
   PVA ratio: 0.8
Polyvinyl alcohol-1
Polyvinylpyrrolidone-1

The PVA ratio in the water-soluble resin was calculated based on the following equation.

$$PVA ratio = PVA / ( PVA + PVP )$$

PVA: Molar amount of a monomer unit constituting a PVA polymer unit
PVP: Molar amount of a monomer unit constituting a PVP polymer unit

“PVA-PVP graft copolymer A” means a graft copolymer in which a hydroxyl group of PVA in PVA-PVP is substituted with a hydrophobic group, and “PVA-PVP copolymer B” means a pure PVA-PVP graft copolymer in which a hydroxyl group of PVA is not substituted with a hydrophobic group. PVP means polyvinylpyrrolidone. Solvent: Dimethyl sulfoxide (DMSO)

10 g of the PVA-PVP graft copolymer A-1 was weighed and dissolved in 100 mL of DMSO to prepare a solution of the PVA-PVP graft copolymer A-1 as a water-soluble resin composition of Sample 1.

A water-soluble resin composition of Sample 2 was prepared in accordance with the same procedure as that of the water-soluble resin composition of Sample 1 except that the PVA-PVP graft copolymer A-1 was changed to the PVA-PVP graft copolymer A-2. Similarly, water-soluble resin compositions of Samples 3 to 8 were prepared by changing the PVA-PVP graft copolymer A-1 to the PVA-PVP graft copolymer A-3, the PVA-PVP graft copolymer B-1, the PVA-PVP graft copolymer B-2, the PVA-PVP graft copolymer B-3, polyvinyl alcohol 1, and polyvinyl pyrrolidone 1, respectively.

### Preparation of Water-Soluble Resin Layer

The water-soluble resin composition of Sample 1 was applied onto a glass substrate (2.5 cm×2.5 cm) by a spin coating method, and then dried by heating at 80° C. for 3 minutes. Thus, a water-soluble resin layer of Sample 1 was formed on the glass substrate. This formed the water-soluble resin layer (thickness 1000 nm) of Sample 1 on the glass substrate. In addition, in accordance with the same procedure as in the case of the water-soluble resin composition of Sample 1, water-soluble resin layers (thickness 1000 nm) of Samples 2 to 8 were separately formed on glass substrates, respectively.

### Evaluation of Dissolution Rate of Water-Soluble Resin Layer

Each of the water-soluble resin layers of Samples 1 to 5 was immersed in pure water (room temperature of about 23° C.) for 60 seconds, then taken out, and subjected to N₂ blow drying at room temperature of 23° C. Thereafter, a thickness of each of the water-soluble resin layers was measured. Then, the dissolution rate in water was calculated based on the difference between the thickness before immersion and the thickness after immersion, and the immersion time in pure water. Table 1 shows the evaluation results of the water-soluble resins contained in the water-soluble resin layers of Samples 1 to 8, the PVA ratios, and the dissolution rates in water.

TABLE 1

| | | | Dissolution rate |
|---|---|---|---|
| | Water-soluble resin | PVA ratio | in water (nm/s) |
| Sample 1 | PVA-PVP graft copolymer A-1 | 0.3 | 100 or more |
| Sample 2 | PVA-PVP graft copolymer A-2 | 0.4 | 50 |
| Sample 3 | PVA-PVP graft copolymer A-3 | 0.5 | 100 or more |
| Sample 4 | PVA-PVP graft copolymer B-1 | 0.6 | 100 or more |
| Sample 5 | PVA-PVP graft copolymer B-2 | 0.7 | 70 |
| Sample 6 | PVA-PVP graft copolymer B-3 | 0.8 | 50 |
| Sample 7 | Polyvinyl alcohol-1 | 1.0 | 30 or less |
| Sample 8 | Polyvinylpyrrolidone-1 | — | 1000 or more |

From the evaluation results of the dissolution rate in water of Samples 1 to 8, it has been confirmed that the higher the PVA ratio, the lower the dissolution rate in water, in other words, the water-soluble resin layer containing PVA tends to have higher water resistance. In addition, it has been confirmed that the water-soluble resin layers of Samples 1 to 6 have the water resistance of the PVA block and the dissolution rate of the PVP block, and thus are more preferable from the viewpoint of thickness control of forming a thickness of several μm. From the evaluation of Samples 1 to 8, it is expected that a light-emitting element is formed in which the light-emitting layer can be successfully protected by the water-soluble resin layer which is a copolymer, and the possibility that the light-emitting layer deteriorates due to moisture infiltrating into the light-emitting layer can be reduced. In particular, a water-soluble resin containing a graft copolymer is expected to be preferable also from the viewpoint of controlling the thickness.

1. A light-emitting element comprising:
first and second electrodes;
a plurality of charge transport layers layered between the first and second electrodes;
a light-emitting layer layered between the plurality of charge transport layers; and
at least one water-soluble resin layer in contact with at least one surface selected from a front surface, a back surface, and an outer peripheral end surface of the light-emitting layer,
wherein the water-soluble resin layer includes a water-soluble resin.

2. The light-emitting element according to claim 1,
wherein the light-emitting layer includes quantum dots.

3. The light-emitting element according to claim 2,
wherein the light-emitting layer including the quantum dots includes a metal sulfide.

4. The light-emitting element according to claim 1,
wherein the water-soluble resin layer includes a positive-working photosensitizer.

5. The light-emitting element according to claim 1,
wherein the water-soluble resin includes a graft copolymer or a block copolymer, and
the graft copolymer and the block copolymer each include at least two polymer units derived from hydrophilic monomers different from each other.

6. The light-emitting element according to claim 5,
wherein a polymer unit in which a vinyl alcohol monomer unit is polymerized is included as the polymer units.

7. The light-emitting element according to claim 5,
wherein a polymer unit in which an N-vinylpyrrolidone monomer unit is polymerized is included as the polymer units.

8. The light-emitting element according to claim 1,
wherein the charge transport layer facing the front surface is an electron transport layer, and the charge transport layer facing the back surface is a hole transport layer.

9. The light-emitting element according to claim 1,
wherein the water-soluble resin layer is in contact with the back surface.

10. The light-emitting element according to claim 9, comprising:
two water-soluble resin layers,
wherein the water-soluble resin layer of a second layer is in contact with the front surface.

11. The light-emitting element according to claim 10,
wherein the water-soluble resin layer is in contact with the outer peripheral end surface of the light-emitting layer.

12. The light-emitting element according to claim 9,
wherein the water-soluble resin layer includes a region in contact with the back surface and a region not in contact with the back surface, and a thickness of the water-soluble resin layer in the region not in contact with the back surface is larger or smaller than a thickness of the water-soluble resin layer in the region in contact with the back surface.

13. The light-emitting element according to claim 9,
wherein the water-soluble resin layer in the region in contact with the back surface has a thickness of 20 nm or less.

14. The light-emitting element according to claim 1,
wherein the charge transport layer and the water-soluble resin layer surround the outer peripheral end surface and are in contact with the outer peripheral end surface.

15. A display device comprising:
a substrate; and
a plurality of light-emitting elements on the substrate,
wherein each of the plurality of light-emitting elements is selected from the light-emitting element according to claim 1.

16. A display device comprising:
a substrate; and
a plurality of light-emitting elements on the substrate,
wherein each of the plurality of light-emitting elements is selected from the light-emitting element according to claim 9, and
one of the plurality of light-emitting elements is a light-emitting element in which the water-soluble resin layer is in contact with the back surface, and the remaining light-emitting elements are light-emitting elements in which the water-soluble resin layer is in contact with the front surface and the back surface.

17. The display device according to claim 15, further comprising:
a non-light-emitting region surrounding each of the plurality of light-emitting elements,
wherein an outer peripheral end portion of a light-emitting layer included in one light-emitting element, a water-soluble resin layer included in the one light-emitting element, and an outer peripheral end portion of a light-emitting layer included in a light-emitting element other than the one light-emitting element overlap each other on the non-light-emitting region, and thus the two light-emitting layers are not in contact with each other.

18. A method for manufacturing a light-emitting element, the light-emitting element including a light-emitting layer, and at least one water-soluble resin layer in contact with the light-emitting layer, a composition for forming the water-soluble resin layer including a water-soluble resin and a positive-working photosensitizer, the method comprising:
water-soluble resin layer formation of applying the composition onto a substrate to form the water-soluble resin layer;
pattern developing of exposing a portion of the water-soluble resin layer to light to develop a pattern on the water-soluble resin layer;
light-emitting layer formation of forming the light-emitting layer in contact with the pattern; and
light-emitting layer peeling and developing of peeling at least a portion of the water-soluble resin layer other than the pattern to peel and develop the light-emitting layer on the pattern.

19. A method for manufacturing a display device, the display device including a plurality of light-emitting elements on a substrate by repeating the water-soluble resin layer formation, the pattern developing, the light-emitting layer formation, and the light-emitting layer peeling and developing included in the method for manufacturing a light-emitting element according to claim 18, the method comprising:
peeling and developing a first light-emitting layer by first peeling and developing;
forming a water-soluble resin layer to cover a front surface of the first light-emitting layer in second water-soluble resin layer formation;
forming a second light-emitting layer by second developing and second light-emitting layer formation; and
leaving the water-soluble resin layer covering the front surface of the first light-emitting layer in second peeling and developing.
